(19) United States
(12) Patent Application Publication
(10) Pub. No.: US 2025/0393243 A1
(43) Pub. Date: Dec. 25, 2025

(54) THIN FILM TRANSISTOR, METHOD FOR MANUFACTURING THE THIN FILM TRANSISTOR AND DISPLAY APPARATUS COMPRISING THE SAME

(71) Applicant: LG Display Co., Ltd., Seoul (KR)

(72) Inventors: Sungju Choi, Gyeonggi-do (KR); Hyeonjoo Seul, Gyeonggi-do (KR); Dongyeon Kang, Gyeonggi-do (KR); Jaeyoon Park, Gyeonggi-do (KR)

(21) Appl. No.: 19/095,709

(22) Filed: Mar. 31, 2025

(30) Foreign Application Priority Data
Jun. 21, 2024 (KR) 10-2024-0081147

(51) Int. Cl. H10D 30/67; H10D 30/01; H10D 86/60

(52) U.S. Cl. CPC H10D 30/6723; H10D 30/0314; H10D 30/6731; H10D 86/60

(57) ABSTRACT

A thin film transistor including a first buffer layer on a first light shielding layer which is on a base substrate; an active layer on the first buffer layer; and a gate electrode spaced apart from, and overlapping at least part of, the active layer. The active layer includes a channel portion overlapping the gate electrode; and first and second connecting portions connected to different sides of the channel portion. The first light shielding layer overlaps the active layer, the first buffer layer includes a protrusion overlapping at least part of the gate electrode in a plane, the channel portion includes a third region overlapping the protrusion and a fourth region not overlapping the protrusion. When the longitudinal direction of the channel portion is a first direction, the third region and the fourth region extend from the first connecting portion to the second connecting portion based on the first direction.

### CROSS-REFERENCE TO RELATED APPLICATIONS

Pursuant to 35 U.S.C. § 119(a), this application claims the benefit of an earlier filing date and right of priority to Korean Patent Application No. 10-2024-0081147 filed on Jun. 21, 2024, the contents of which are incorporated by reference herein in their entirety.

### TECHNICAL FIELD

The present disclosure relates to a thin film transistor, method for manufacturing the thin film transistor and display apparatus comprising the same.

### BACKGROUND

Transistors are widely used as switching devices or driving devices in the field of electronic devices. In particular, since a thin film transistor may be manufactured on a glass substrate or a plastic substrate, it is widely used as a switching device of a display apparatus such as a liquid crystal display apparatus or an organic light emitting device.

The display device may include, for example, a switching thin film transistor and a driving thin film transistor. In general, it is advantageous for the switching thin film transistor to have a small s-factor for improving the on-off characteristics, and it is advantageous for the driving thin film transistor to have a large s-factor for expressing gray scale.

Generally, thin film transistors often have a small s-factor for securing the on-off characteristics. When these thin film transistors are applied to the driving thin film transistor of the display device, it is difficult to express the gray scale of the display device.

Therefore, in order to easily express the gray scale by applying the driving thin film transistor of the display device, a thin film transistor having a large s-factor is required. In addition, even if the thin film transistor has a large s-factor, it is required to have excellent current characteristics in the on state.

### SUMMARY

The present disclosure has been made in view of the above problems and it is an object of the present disclosure to provide a thin film transistor having a large s-factor and excellent current characteristics in the ON state.

One implementation of the present disclosure is to provide a thin film transistor having excellent current characteristics and a large s-factor by controlling the size of capacitance (Cap) in the direction of the width of the channel.

Another implementation of the present disclosure is to provide a method for manufacturing a thin film transistor.

Another implementation of the present disclosure is to provide a display device including such a thin film transistor.

In accordance with an aspect of the present disclosure, the above and other objects can be accomplished by the provision of a thin film transistor including: a base substrate; a first light shielding layer on the base substrate; a first buffer layer on the first light shielding layer; an active layer on the first buffer layer; and a gate electrode spaced apart from the active layer and overlapping at least a portion of the active layer, wherein the active layer includes a channel portion overlapping the gate electrode; a first connecting portion connected to one side of the channel portion; and a second connecting portion connected to the other side of the channel portion, wherein the first light shielding layer overlaps the active layer, the first buffer layer includes a trench overlapping at least a portion of the gate electrode in a plane, and the channel portion includes a first region overlapping the trench and a second region not overlapping the trench, and when the longitudinal direction of the channel portion is a first direction, the first region and the second region extend from the first connecting portion to the second connecting portion based on the first direction.

The effective gate voltage applied to the first region may be different from the effective gate voltage applied to the second region.

The distance between the upper surface of the base substrate and the upper surface of the active layer overlapping the trench may be shorter than the distance between the upper surface of the base substrate and the upper surface of the active layer not overlapping the trench.

The thin film transistor may further include a second light shielding layer disposed on the first light shielding layer and overlapping the active layer, and a second buffer layer disposed between the first light shielding layer and the second light shielding layer.

The second light shielding layer may include a hole overlapping the trench in a plane, and the entire area of the hole may overlap the trench in a plane.

The trench may include at least one of a first trench overlapping the first connecting portion; and a second trench overlapping the second connecting portion; and the first trench and the second trench may be spaced apart from each other.

The first trench may include a first sub-trench and a second sub-trench that are spaced apart from each other, and the second trench may include a first sub-trench and a second sub-trench that are spaced apart from each other.

The trench may include a third trench that does not overlap the first connecting portion and the second connecting portion.

The third trench may include a first sub-trench and a second sub-trench that are spaced apart from each other.

The trench includes the first trench and the second trench, and any straight line parallel to the first direction and passing through the first trench can pass through the second trench.

The trench includes the first trench and the second trench, and any straight line parallel to the first direction and passing through the first trench may not pass through the second trench.

Another implementation of the present disclosure seek to provide a thin film transistor including a base substrate; a first light shielding layer on the base substrate; a first buffer layer on the first light shielding layer; an active layer on the first buffer layer; and a gate electrode spaced apart from the active layer and overlapping at least a portion of the active layer; wherein the active layer includes a channel portion overlapping the gate electrode; a first connecting portion connected to one side of the channel portion; and a second connecting portion connected to the other side of the channel portion; wherein the first light shielding layer overlaps the active layer, the first buffer layer includes a protrusion that overlaps at least a portion of the gate electrode in a plane, the channel portion includes a third region overlapping the protrusion and a fourth region not overlapping the protrusion, and when the longitudinal direction of the channel portion is a first direction, the third region and the fourth region extend from the first connecting portion to the second connecting portion based on the first direction.

An effective gate voltage applied to the third region may be different from an effective gate voltage applied to the fourth region.

A distance between an upper surface of the base substrate and an upper surface of the active layer overlapping the protrusion may be longer than a distance between an upper surface of the base substrate and an upper surface of the active layer not overlapping the protrusion.

The thin film transistor comprising a third light shielding layer disposed on the first light shielding layer and overlapping the protrusion, and a second buffer layer disposed between the first light shielding layer and the third light shielding layer, and the entire area of the third light shielding layer can overlap the protrusion in a plane view.

The protrusion includes at least one of a first protrusion overlapping the first connecting portion; and a second protrusion overlapping the second connecting portion; and the first protrusion and the second protrusion can be spaced apart from each other.

The first protrusion can include a first sub-protrusion and a second sub-protrusion that are spaced apart from each other, and the second protrusion can include a first sub-protrusion and a second sub-protrusion that are spaced apart from each other.

The protrusion can include a third protrusion that does not overlap the first connecting portion and the second connecting portion.

The third protrusion can include a first sub-protrusion and a second sub-protrusion that are spaced apart from each other.

The protrusion includes the first protrusion and the second protrusion, and any straight line parallel to the first direction, passing through the first protrusion may pass through the second protrusion.

The protrusion includes the first protrusion and the second protrusion, and any straight line parallel to the first direction, passing through the first protrusion may not pass through the second protrusion.

An implementation of the present disclosure provides a method for manufacturing a thin film transistor, comprising a steps of forming a first light shielding layer; forming a first buffer layer on the first light shielding layer; forming a trench by etching a portion of the first buffer layer; forming an active layer on the first buffer layer; forming a gate insulating film on the active layer; and a step of forming a gate electrode on the gate insulating film, spaced apart from the active layer and overlapping at least a portion of the active layer, the trench overlaps at least a portion of the gate electrode in a plane view, the active layer includes a channel portion overlapping the gate electrode, a first connecting portion connected to one side of the channel portion, and a second connecting portion connected to the other side of the channel portion, the channel portion includes a first region overlapping the trench and a second region not overlapping the trench, and when the longitudinal direction of the channel portion is a first direction, the first region and the second region extend from the first connecting portion to the second connecting portion based on the first direction.

Another implementation of the present disclosure provides a method for manufacturing a thin film transistor comprising: a steps of forming a first light shielding layer; forming a first buffer layer on the first light shielding layer; forming a protrusion by etching a portion of the first buffer layer; forming an active layer on the first buffer layer; forming a gate insulating film on the active layer; and a step of forming a gate electrode on the gate insulating film, spaced apart from the active layer and overlapping at least a portion of the active layer, wherein the protrusion overlaps at least a portion of the gate electrode in a plane view, the active layer includes a channel portion overlapping the gate electrode, a first connecting portion connected to one side of the channel portion, and a second connecting portion connected to the other side of the channel portion, and the channel portion includes a third region overlapping the protrusion and a fourth region not overlapping the protrusion, and when the longitudinal direction of the channel portion is a first direction, the third region and the fourth region extend from the first connecting portion to the second connecting portion based on the first direction.

Another implementation of the present disclosure provides a display device including the thin film transistor.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to an implementation of the present disclosure.

FIG. 2 is a cross-sectional view taken along line I-I′ of FIG. 1.

FIG. 3 is a cross-sectional view taken along line II-II′ of FIG. 1.

FIG. 4 is a plan view of a thin film transistor according to another implementation of the present disclosure.

FIG. 5 is a cross-sectional view taken along line III-III′ of FIG. 4.

FIG. 6 is a cross-sectional view taken along line IV-IV′ of FIG. 4.

FIG. 7 is a plan view of a thin film transistor according to another implementation of the present disclosure.

FIG. 8 is a cross-sectional view taken along line V-V′ of FIG. 7.

FIG. 9 is a plan view of a thin film transistor according to another implementation of the present disclosure.

FIG. 10 is a cross-sectional view taken along line VI-VI′ of FIG. 9.

FIG. 11 is a plan view of a thin film transistor according to another implementation of the present disclosure.

FIG. 12 is a plan view of a thin film transistor according to another implementation of the present disclosure.

FIG. 13 is a plan view of a thin film transistor according to another implementation of the present disclosure.

FIG. 14 is a plan view of a thin film transistor according to another implementation of the present disclosure.

FIG. 15 is a cross-sectional view taken along line VII-VII′ of FIG. 14.

FIG. 16 is a cross-sectional view taken along line VIII-VIII′ of FIG. 14.

FIG. 17 is a plan view of a thin film transistor according to another implementation of the present disclosure.

FIG. 18 is a cross-sectional view taken along line IX-IX′ of FIG. 17.

FIG. 19 is a cross-sectional view taken along line X-X′ of FIG. 17.

FIG. 20 is a plan view of a thin film transistor according to another implementation of the present disclosure.

FIG. 21A and FIG. 21B are schematic diagrams explaining effective gate voltages of thin film transistors.

FIG. 21C and FIG. 21D are schematic diagrams illustrating effective gate voltages of thin film transistors according to one implementation of the present disclosure.

FIG. 22A is a plan view of a thin film transistor according to an implementation.

FIG. 22B is a graph showing current characteristics in a thin film transistor according to FIG. 22A.

FIG. 23A is a plan view of a thin film transistor according to another implementation.

FIG. 23B is a graph showing current characteristics in a thin film transistor according to FIG. 23A.

FIG. 24 is a process diagram showing a method for manufacturing a thin film transistor according to one implementation of the present disclosure.

FIG. 25 is a process diagram showing a method for manufacturing a thin film transistor according to another implementation of the present disclosure.

FIG. 26 is a schematic diagram of a display device according to one implementation of the present disclosure.

FIG. 27 is a circuit diagram for one pixel of FIG. 26.

FIG. 28 is a plan view for a pixel of FIG. 27. FIG. 29 is a cross-sectional view taken along line XI-XI′ of FIG. 28.

### DETAILED DESCRIPTION OF THE DISCLOSURE

Advantages and features of the present disclosure and implementation methods thereof will be clarified through following implementations described with reference to the accompanying drawings. The present disclosure may, however, be embodied in different forms and should not be construed as limited to the implementations set forth herein. Rather, these implementations are provided so that this disclosure will be thorough and complete and will fully convey the scope of the present disclosure to those skilled in the art.

A shape, a size, a ratio, an angle and a number disclosed in the drawings for describing implementations of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various implementations of the present disclosure may be partially or overall coupled to or combined with each other and may be variously inter-operated with each other and driven technically as those skilled in the art can sufficiently understand. The implementations of the present disclosure may be carried out independently from each other or may be carried out together in a co-dependent relationship.

In the addition of reference numerals to the components of each drawing describing implementations of the present disclosure, the same components can have the same sign as can be displayed on the other drawings.

In the implementations of the present disclosure, a source electrode and a drain electrode are distinguished for convenience of description, and the source electrode and the drain electrode may be interchanged. The source electrode may be the drain electrode and vice versa. In addition, the source electrode of any one implementation may be a drain electrode in another implementation, and the drain electrode of any one implementation may be a source electrode in another implementation.

In some implementations of the present disclosure, for convenience of description, a source area is distinguished from a source electrode, and a drain area is distinguished from a drain electrode, but implementations of the present disclosure are not limited thereto. The source area may be the source electrode, and the drain area may be the drain electrode. In addition, the source area may be the drain electrode, and the drain area may be the source electrode.

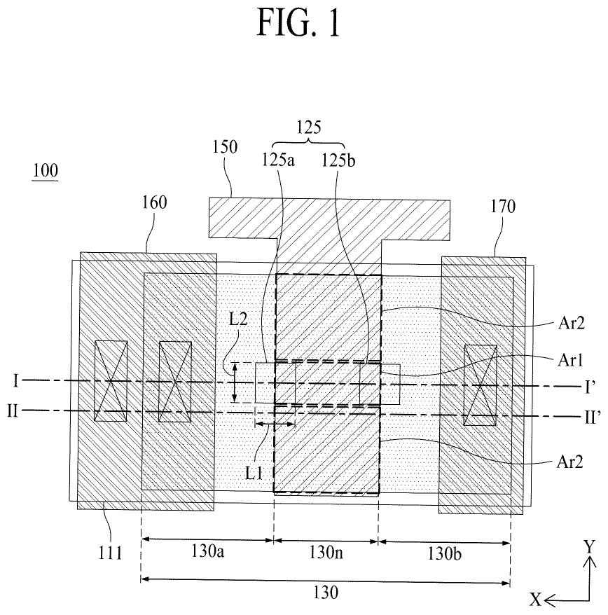

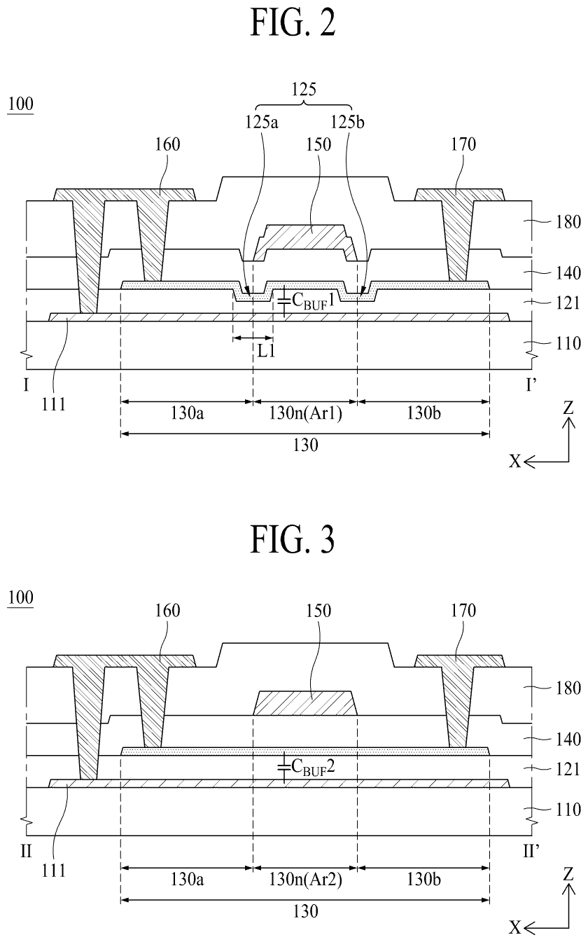

FIG. 1 is a plan view of a thin film transistor (100) according to one implementation of the present disclosure. FIG. 2 is a cross-sectional view taken along line I-I′ of FIG. 1. FIG. 3 is a cross-sectional view taken along line II-II′ of FIG. 1.

Referring to FIG. 1, FIG. 2, and FIG. 3, a thin film transistor (100) according to one implementation of the present disclosure may include a first light shielding layer (111), a first buffer layer (121), an active layer (130), and a gate electrode (150).

Specifically, referring to FIGS. 1, 2, and 3, it may include a first light shielding layer (111) on a base substrate (110), a first buffer layer (121) on the first light shielding layer (111), an active layer (130) on the first buffer layer (121), and a gate electrode (150) spaced apart from the active layer (130) and at least partially overlapping the active layer (130).

According to one implementation of the present disclosure, the thin film transistor (100) may further include a base substrate (110). Referring to FIGS. 2 and 3, the first light shielding layer (111) is disposed on the base substrate (110).

According to one implementation of the present disclosure, the thin film transistor (100) may further include a gate insulating film (140). Referring to FIGS. 2 and 3, the gate insulating film (140) is disposed on the active layer (130). Specifically, the gate insulating film (140) is disposed between the active layer (130) and the gate electrode (150).

According to one implementation of the present disclosure, the thin film transistor (100) may further include an interlayer insulating film (180). Referring to FIGS. 2 and 3, the interlayer insulating film (180) is disposed on the gate electrode (150). Specifically, the gate electrode (150) is disposed between the gate insulating film (140) and the interlayer insulating film (180).

According to one implementation of the present disclosure, the thin film transistor (100) may further include a source electrode (160) and a drain electrode (170). Referring to FIGS. 1, 2, and 3, the source electrode (160) and the drain electrode (170) are disposed on the interlayer insulating film (180).

Hereinafter, the components of the thin film transistor (100) according to one implementation of the present disclosure will be described in more detail.

The base substrate (110) may be made of glass or plastic. A transparent plastic having flexible properties, such as polyimide, may be used as the plastic.

When polyimide is used as the base substrate (110), considering that a high-temperature deposition process is performed on the base substrate (110), a heat-resistant polyimide that can withstand high temperatures can be used. In this case, in order to form a thin film transistor, processes such as deposition and etching can be performed while the polyimide substrate is placed on a carrier substrate made of a highly durable material such as glass.

Referring to FIGS. 2 and 3, a first light shielding layer (111) can be placed on the base substrate (110).

The first light shielding layer (111) can be placed between the base substrate (110) and the first buffer layer (121). The first light shielding layer (111) overlaps the active layer (130). Specifically, the first light shielding layer (111) can overlap the channel portion (130n). The first light shielding layer (111) blocks light incident from the outside and protects the channel portion (130n).

The first light shielding layer (111) may be made of a material having light shielding properties. The first light shielding layer (111) may include at least one of an aluminum-based metal such as aluminum (Al) or an aluminum alloy, a molybdenum-based metal such as molybdenum (Mo) or a molybdenum alloy, chromium (Cr), tantalum (Ta), neodymium (Nd), titanium (Ti), and iron (Fe). According to one implementation of the present disclosure, the first light shielding layer (111) may have electrical conductivity.

Referring to FIGS. 2 and 3, a first buffer layer (121) may be arranged on the first light shielding layer (111).

The first buffer layer (121) is formed on the base substrate (110) and may be formed of an inorganic material or an organic material. For example, it may include an insulating oxide such as silicon oxide (SiOx) or aluminum oxide (Al2O3).

The first buffer layer (121) blocks impurities such as moisture and oxygen flowing in from the base substrate (110) to protect the active layer (130) and serves to flatten the upper portion of the base substrate (110), and may be formed as a single layer or multiple layers.

If the first buffer layer (121) is a multiple layer, each of the multiple layers may be formed of different materials.

Referring to FIGS. 2 and 3, the active layer (130) may be arranged on the first buffer layer (121).

The active layer (130) may include a channel portion (130n), a first connecting portion (130a), and a second connecting portion (130b).

Specifically, the active layer (130) may include a channel portion (130n) that overlaps the gate electrode (150) in a plane view, a first connecting portion (130a) that does not overlap the gate electrode (150) in a plane view and is connected to one side of the channel portion (130n), and a second connecting portion (130b) that does not overlap the gate electrode (150) in a plane view and is connected to the other side of the channel portion (130n).

According to one implementation of the present disclosure, the first connecting portion (130a) and the second connecting portion (130b) are spaced apart from each other with the channel portion (130n) interposed therebetween.

According to one implementation of the present disclosure, the active layer (130) may be formed of a semiconductor material. The active layer (130) may include an oxide semiconductor material.

The oxide semiconductor material may be, for example, an InZnO (IZO)-based oxide semiconductor material, an InGaO (IGO)-based oxide semiconductor material, an ITO (InSnO)-based oxide semiconductor material, an IGZO (InGaZnO)-based oxide semiconductor material, an IGZTO (InGaZnSnO)-based oxide semiconductor material, GZTO (GaZnSnO)-based oxide semiconductor material, GZO (GaZnO)-based oxide semiconductor material, ITZO (InSnZnO)-based oxide semiconductor material, and FIZO (FeInZnO)-based oxide semiconductor material. However, one implementation of the present disclosure is not limited thereto, and the active layer 130 may be made of other oxide semiconductor materials known in the art.

The first connecting portion (130a) and the second connecting portion (130b) may be formed by selectively conductorized with respect to the active layer (130) made of a semiconductor material. According to one implementation of the present disclosure, selectively conductorization is used to impart conductivity to a specific portion of the active layer (130) so that it can act as a conductor.

For example, the active layer (130) can be selectively conductorized by ion doping. As a result, the first connecting portion (130a) and the second connecting portion (130b) can be formed. However, one implementation of the present disclosure is not limited thereto, and the active layer (130) can be selectively conductorized by other methods known in the art. The first connecting portion (130a) and the second connecting portion (130b) do not overlap with the gate electrode (150).

The first connecting portion (130a) and the second connecting portion (130b) have superior electrical conductivity and high mobility compared to the channel portion (130n). Therefore, the first connecting portion (130a) and the second connecting portion (130b) can each act as wiring.

According to one implementation of the present disclosure, the active layer (130) may have a multilayer structure. For example, although not shown in the drawing, the active layer (130) may include a first active layer and a second active layer.

The first active layer and the second active layer may include the same semiconductor material, or may include different semiconductor materials.

According to one implementation of the present disclosure, the thin film transistor (100) may further include a gate insulating film (140) between the active layer (130) and the gate electrode (150). Specifically, the gate insulating film (140) may cover the entire upper surface of the active layer (130). FIG. 2 illustrates a configuration in which the gate insulating film (140) covers the entire upper surface of the active layer (130).

However, one implementation of the present disclosure is not limited thereto, and the first connecting portion (130a) and the second connecting portion (130b) of the active layer (130) may be exposed from the gate insulating film (140).

The gate insulating film (140) may include at least one of silicon oxide, silicon nitride, and metal oxide. The gate insulating film (140) may have a single film structure or a multilayer film structure. The gate insulating film (140) protects the channel portion (130n).

Referring to FIG. 2, the gate electrode (150) is disposed on the gate insulating film (140). The gate electrode (150) overlaps the channel portion (130n) of the active layer (130).

The gate electrode (150) may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode (150) may have a multilayer structure including at least two conductive films having different physical properties.

Referring to FIG. 2, an interlayer insulating film (180) is disposed on the gate electrode (150) and the gate insulating film (140). The interlayer insulating film (180) is an insulating layer made of an insulating material. The interlayer insulating film (180) may be made of an organic material, an inorganic material, or a laminate of an organic layer and an inorganic layer.

Referring to FIG. 2, a source electrode (160) and a drain electrode (170) are arranged on an interlayer insulating film (180).

Although not shown in the drawing, the source electrode (160) and the drain electrode (170) are arranged on a gate insulating film (140) and may be arranged on the same layer as the gate electrode (150). The source electrode (160) and the drain electrode (170) may be made of the same material as the gate electrode (150) and by the same process.

The source electrode (160) and the drain electrode (170) may each include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The source electrode (160) and the drain electrode (170) may each have a multilayer film structure including at least two conductive films having different physical properties.

Referring to FIGS. 1 and 2, the source electrode (160) and the drain electrode (170) are each connected to the active layer (130) through a contact hole. Specifically, the source electrode (160) and the drain electrode (170) are connected to the active layer (130) by contacting the first connecting portion (130a) and the second connecting portion (130b).

According to one implementation of the present disclosure, the first buffer layer (121) includes a trench (125). Below, the trench (125) of the first buffer layer (121) is described in detail.

According to one implementation of the present disclosure, the trench (125) may overlap at least a portion of the gate electrode (150) in a plane view. FIG. 1 illustrates a shape in which the trench (125) overlaps the gate electrode (150) in a plane view.

According to one implementation of the present disclosure, the active layer (130) is arranged inside the trench (125).

According to one implementation of the present disclosure, the trench (125) means a region that is partially etched in the first buffer layer (121), or a region surrounded by a first buffer layer (121) that is not etched in a plane view among the first buffer layer (121), or a region in which the upper surface of the first buffer layer (121) is arranged closer to the upper surface of the base substrate (110) compared to other regions of the first buffer layer (121) among the first buffer layers (121).

According to one implementation of the present disclosure, the longitudinal direction of the channel portion (130n) may be referred to as the first direction (X), and the direction perpendicular to the first direction (X) may be referred to as the second direction (Y). Specifically, the first direction (X) corresponds to the direction of a straight line parallel to the line segment connecting the first connecting portion (130a) and the second connecting portion (130b) at the shortest distance, and the second direction (Y) corresponds to the width direction of the channel portion (130n).

According to one implementation of the present disclosure, the trench (125) may have a length (L1) of 1 μm or more based on the first direction (X). In addition, it may have a width (L2) of 1 μm or more based on the second direction (Y).

Referring to FIG. 1, the trench (125) may have a length (L1) of 1 μm or more based on the first direction (X) and a width (L2) of 1 μm or more based on the second direction (Y).

If the length (L1, L2) of the trench (125) in the first direction (X) or the second direction (Y) is less than 1 μm, a problem of unexpected parasitic resistance or capacitance may occur.

The length (L1) means the maximum length of the trench (125) based on the first direction (X), and the width (L2) means the maximum width of the trench (125) based on the second direction (Y).

In FIG. 2, the length (L1) of the trench (125) is illustrated, and the length (L1) is measured based on the tops on the left and right sides of the trench (125) in a plane view. Although the width (L2) of the trench (125) is not shown in the drawing, the width (L2) of the trench (125) is also measured based on the tops on the left and right sides in the cross section, just like the length (L1) in a plane view.

In FIG. 1, the trench (125) is illustrated as having a rectangular shape in plan view. However, one implementation of the present disclosure is not limited thereto, and may have a shape such as a polygon, a circle, or a bow.

According to one implementation of the present disclosure, one of the arbitrary straight lines parallel to the first direction (X) within the area occupied by the active layer (130) in plane view may intersect with the trench (125), and the other of the arbitrary straight lines parallel to the first direction (X) within the area occupied by the active layer (130) in plane view may not intersect with the trench (125).

For example, referring to FIGS. 1, 2, and 3, a straight line corresponding to an extension of I-I′ among straight lines parallel to the first direction (X) intersects with the trench (125). On the other hand, a straight line corresponding to an extension of II-II′ among straight lines parallel to the first direction (X) does not intersect with the trench (125).

Specifically, among any straight lines parallel to the first direction (X), a straight line intersecting with the trench (125) and a straight line not intersecting with the trench (125) are arranged side by side along the second direction (Y).

According to one implementation of the present disclosure, the channel portion (130n) includes a first region (Ar1) overlapping with the trench (125) and a second region (Ar2) not overlapping with the trench (125).

The first region (Ar1) and the second region (Ar2) can extend from the first connecting portion (130a) to the second connecting portion (130b). Specifically, the first region (Ar1) and the second region (Ar2) are in contact with the first connecting portion (130a) and the second connecting portion (130b), respectively. More specifically, the first region (Ar1) and the second region (Ar2) can extend from the first connecting portion (130a) to the second connecting portion (130b) based on the first direction (X).

Referring to FIG. 2, a part of the first region (Ar1) of the channel portion (130n) is disposed on the trench (125).

Referring to FIG. 3, the second region (Ar2) of the channel portion (130n) is not disposed on the trench (125).

According to one implementation of the present disclosure, an active layer (130) is disposed on a trench (125). Specifically, the active layer (130) disposed on the trench (125) is formed along the upper surface of the trench (125).

According to one implementation of the present disclosure, the distance between the upper surface of the base substrate (110) and the upper surface of the active layer (130) overlapping the trench (125) is shorter than the distance between the upper surface of the base substrate (110) and the upper surface of the active layer (130) not overlapping the trench (125).

FIG. 2 illustrates that the distance between the upper surface of the base substrate (110) and the upper surface of the active layer (130) overlapping the trench (125) is shorter than the distance between the upper surface of the base substrate (110) and the upper surface of the active layer (130) not overlapping the trench (125).

FIG. 3 illustrates a case where a trench (125) is not arranged. The distance between the upper surface of the active layer (130) illustrated in FIG. 3 and the upper surface of the base substrate (110) is the same as the distance between the upper surface of the active layer (130) and the base substrate (110) that does not overlap the trench (125) illustrated in FIG. 2.

According to one implementation of the present disclosure, since the first light shielding layer (111) is connected to the source electrode (160), the same voltage as the source electrode (160) can be applied to the first light shielding layer (111). Since the first light shielding layer (111) is arranged between the base substrate (110) and the active layer (130), the voltage applied to the first light shielding layer (111) can affect the channel portion (130n).

For example, due to the electrical influence by the first light shielding layer (111), the electric field effect applied to the channel portion (130n) by the gate electrode (150) may be selectively reduced. Specifically, an electric field is applied to the channel portion (130n) by the gate electrode (150), and due to the electrical influence by the first light shielding layer (111), the electric field effect applied to the channel portion (130n) may be selectively reduced.

According to one implementation of the present disclosure, a decrease in the effective gate voltage (Veff) may occur in a region of the channel portion (130n) that is arranged close to the first light shielding layer (111). As a result, the effective gate voltage (Veff) applied to the channel portion (130n) arranged on the trench (125) may be smaller than the effective gate voltage (Veff) applied to the channel portion (130n) that is not arranged on the trench (125).

In this way, when a decrease in the effective gate voltage (Veff) occurs in the channel portion (130n), the s-factor of the thin film transistor (100) may increase.

The s-factor is described in detail below.

The s-factor (sub-threshold swing: s-factor) is obtained as the reciprocal value of the slope of the graph of the drain-source current (IDS) for the gate voltage of the thin film transistor (100) in the threshold voltage (Vth) section. The s-factor can be used as an indicator of the degree of change in the drain-source current (IDS) for the gate voltage in the threshold voltage (Vth) section of the thin film transistor (100), for example.

As the s-factor increases, the rate of change in the drain-source current (IDS) for the gate voltage in the threshold voltage (Vth) section becomes gentler.

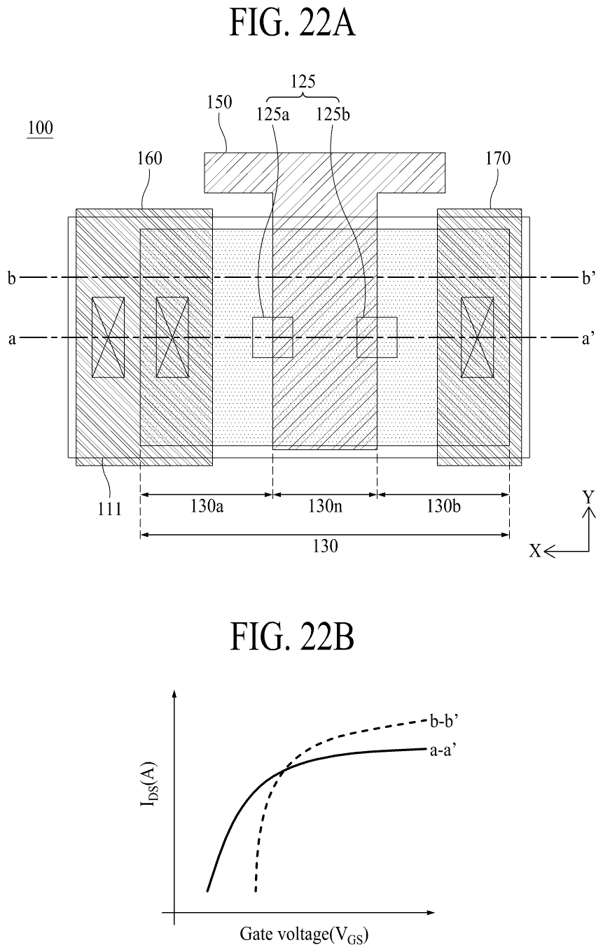

The s-factor can be explained, for example, by the current change graph illustrated in FIG. 22B. Specifically, FIG. 22B shows the drain-source current (IDS) for the gate voltage (VGS). In the threshold voltage (Vth) section of the graph illustrated in FIG. 22B, the reciprocal of the slope of the drain-source current (IDS) graph with respect to the gate voltage (VGS) is the s-factor. If the slope of the graph is steep, the s-factor (s-factor) is small, and if the slope of the graph is small, the s-factor (s-factor) is large. If the s-factor (s-factor) is large, the drain-source current (IDS) change rate with respect to the gate voltage in the threshold voltage (Vth) section is gradual.

As the s-factor (s-factor) increases, the drain-source current (IDS) change rate with respect to the gate voltage (VGS) in the threshold voltage (Vth) section becomes gradual, so it becomes easy to control the size of the drain-source current (IDS) by controlling the gate voltage (VGS).

In a current-driven display device, for example, an organic light-emitting display device, the gray scale of a pixel can be controlled by adjusting the magnitude of the drain-source current (IDS) of the driving thin film transistor. The magnitude of the drain-source current (IDS) of the driving thin film transistor is determined by the gate voltage (VGS). Therefore, in an organic light-emitting display device driven by current, the larger the s-factor of the driving thin film transistor (Driving TR), the easier it is to adjust the gray scale of the pixel.

Referring to FIGS. 1, 2, and 3, since the first region (Ar1) disposed on the trench (125) among the channel portions (130n) is disposed closer to the first light shielding layer (111) compared to the second region (Ar2), the effective gate voltage (Veff) in the channel portions (130n) decreases, so that the s-factor (s-factor) of the thin film transistor (100) can increase.

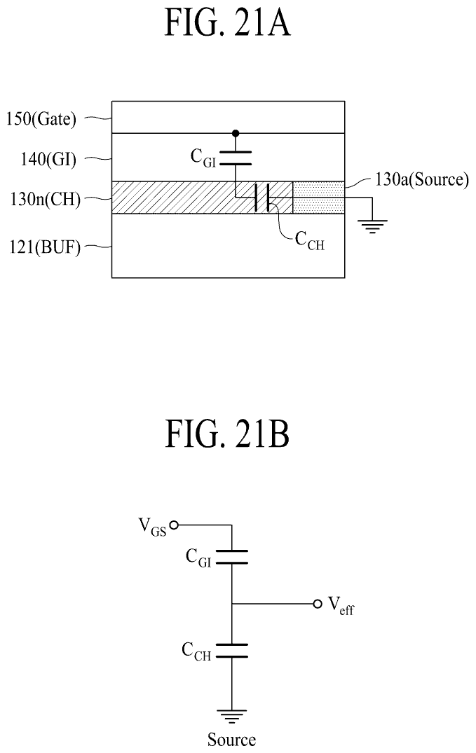

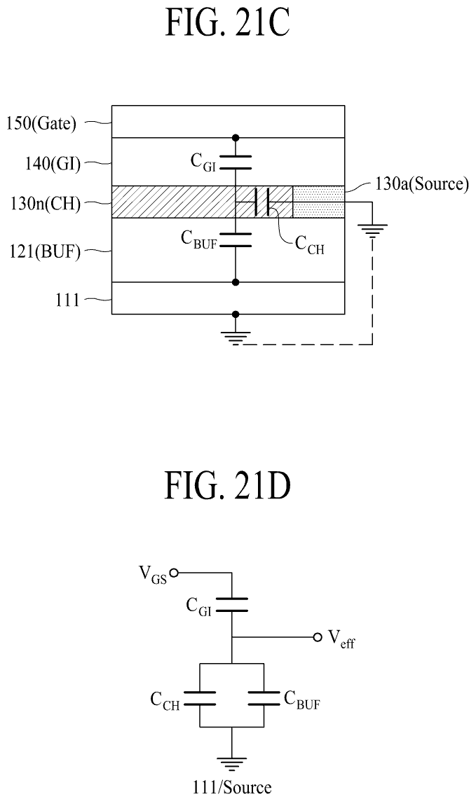

The effect of the first light shielding layer (111) on the s-factor of the thin film transistor (100) can be explained by FIGS. 21A, 21B, 21C, and 21D.

FIG. 21A and FIG. 21B are schematic diagrams explaining the effective gate voltage (Veff) of a thin film transistor. Specifically, FIG. 21A and FIG. 21B are schematic diagrams explaining the effective gate voltage (Veff) of a thin film transistor (comparative example) having a structure similar to FIG. 1 to FIG. 3 but not having a first light shielding layer (111).

FIG. 21A schematically illustrates a capacitance (Cap) that may occur when a gate voltage (VGS) is applied to a thin film transistor. Here, the gate voltage (VGS) is a voltage between a source electrode (160) and a gate electrode (150). According to one implementation of the present disclosure, the gate voltage (VGS) may also be referred to as a voltage between a first connecting portion (130a) and a gate electrode (150).

FIG. 21A schematically explains the capacitance (Cap) relationship at a voltage near the threshold voltage (Vth) before the thin film transistor is completely turned on.

As shown in FIG. 21A, when a gate voltage (VGS) is applied to a thin film transistor that does not have a first light shielding layer (111), a capacitance (CGI) is formed between the channel portion (130n) of the active layer (130) and the gate electrode (150) (Gate), and also, a capacitance (CCH) may be formed between the channel portion (130n) and the first connecting portion (130a) (Source).

The capacitance (CCH) formed between the channel portion (130n) and the first connecting portion (130a) (Source) can be said to be formed by the voltage difference between the drain electrode (170), which is a high voltage terminal, and the source electrode (160), which is a low voltage terminal, in the channel portion (130n) made of an oxide semiconductor layer having N-type semiconductor characteristics.

The relationship between the capacitance (Cap) and the voltage according to FIG. 21A can be expressed as in FIG. 21B. Referring to FIG. 21B, due to the capacitance (CCH) between the channel portion (130n) and the first connecting portion (130a) (Source), the gate voltage (VGS) cannot be effectively applied to the channel portion (130n). As a result, voltage loss may occur.

In FIG. 21B, when driving a thin film transistor, when the voltage effectively applied to the channel portion (130n) among the gate voltages (VGS) is referred to as the effective gate voltage (Veff), the effective gate voltage (Veff) can be obtained by the following equation 1.

$$Veff = [ CGI / ( CGI + CCH ) ] \times VGS \qquad [ Formula 1 ]$$

FIGS. 21C and 21D are schematic diagrams explaining the effective gate voltage (Veff) of a thin film transistor (100) according to one implementation of the present disclosure.

FIG. 21C schematically illustrates the capacitance (Cap) that may occur when a gate voltage (VGS) is applied to a thin film transistor (100) according to one implementation of the present disclosure. FIG. 21C schematically explains the capacitance (Cap) relationship at a voltage near the threshold voltage (Vth) before the thin film transistor (100) is completely turned on.

As illustrated in FIG. 21C, when a gate voltage (VGS) is applied to a thin film transistor (100), a capacitance (CGI) is formed between the channel portion (130n) of the active layer (130) and the gate electrode (150), a capacitance (CCH) is formed between the channel portion (130n) and the first connecting portion (130a) (Source), and additionally, a capacitance (CBUF) may be formed between the channel portion (130n) and the first light shielding layer (111).

Referring to FIG. 1 and FIG. 2, a capacitance (CBUF1) may be formed between the first region (Ar1) of the channel portion (130n) and the first light shielding layer (111), and a capacitance (CBUF2) may be formed between the second region (Ar2) of the channel portion (130n) and the first light shielding layer (111).

The capacitance (CBUF) between the channel portion (130n) and the first light shielding layer (111) is formed by the sum of the capacitance (CBUF1) between the first region (Ar1) of the channel portion (130n) and the first light shielding layer (111) and the capacitance (CBUF2) between the second region (Ar2) of the channel portion (130n) and the first light shielding layer (111).

In addition, the relationship between capacitance (Cap) and voltage according to FIG. 21C can be expressed as in FIG. 21D. Referring to FIG. 21D, due to the capacitance (CCH) between the channel portion (130n) and the first connecting portion (130a) (Source) and the capacitance (CBUF) between the channel portion (130n) and the first light shielding layer (111), the gate voltage (VGS) is not effectively applied to the channel portion (130n), and voltage loss may occur.

According to one implementation of the present disclosure, since the first light shielding layer (111), the source electrode (160), and the first connecting portion (130a) are electrically connected, an additional capacitance (CBUF) is generated between the channel portion (130n) and the first light shielding layer (111), so that the lower capacitance (CCH+CBUF), which causes voltage loss, increases.

Specifically, when the voltage effectively applied to the channel portion (130n) among the gate voltages (VGS) in FIG. 21D is called the effective gate voltage (Veff), the effective gate voltage (Veff) can be obtained by the following equation 2.

$$Veff = [ CGI / ( CGI + CCH + CBUF ) ] \times VGS \qquad [ Formula 2 ]$$

Referring to formula 2, since the denominator part of formula 2 increases due to the capacitance (CBUF) between the channel portion (130n) and the first light shielding layer (111), the decrease in the effective gate voltage (Veff) is relatively greater than that in formula 1. Accordingly, when the gate voltage (VGS) is applied, the increase speed of the drain-source current (IDS) in the thin film transistor (100) according to one implementation of the present disclosure decreases, and as a result, the effect of increasing the s-factor occurs.

According to one implementation of the present disclosure, the capacitance (CBUF1) between the first region (Ar1) of the channel portion (130n) and the first light shielding layer (111) is greater than the capacitance (CBUF2) between the second region (Ar2) of the channel portion (130n) and the first light shielding layer (111). As a result, the effective gate voltage (Veff) in the first region (Ar1) located close to the first light shielding layer (111) of the channel portion (130n) may be significantly reduced.

In other words, the thin film transistor (100) according to one implementation of the present disclosure may have capacitances of different sizes arranged in parallel in the width direction.

Therefore, according to one implementation of the present disclosure, the magnitude of the effective gate voltage (Veff) applied to the first region (Ar1) is smaller than the magnitude of the effective gate voltage (Veff) applied to the second region (Ar2).

According to one implementation of the present disclosure, since the effective gate voltage (Veff) in the first region (Ar1) of the channel portion (130n) is relatively small, the current (IDS) increase speed is delayed in the threshold voltage (Vth) section before the thin film transistor (100) is completely turned on, thereby causing an effect of increasing the s-factor. In this way, according to one implementation of the present disclosure, since the first buffer layer (121) has a trench (125) structure, the s-factor of the thin film transistor (100) can be increased without increasing the gap between the channel portion (130n) and the gate electrode (150).

According to one implementation of the present disclosure, since the gap between the channel portion (130n) and the gate electrode (150) is not increased, the ON current of the thin film transistor (100) is not reduced when the thin film transistor (100) is turned on. In particular, the area of the channel portion (130n) that is not disposed on the trench (125) becomes the main current area, thereby improving the ON current characteristics of the thin film transistor (100).

In the past, in order to increase the s-factor of a thin film transistor, a method of increasing the distance between the gate electrode and the channel region was applied. In this case, there was a problem that the s-factor increased but the ON current of the thin film transistor decreased.

On the other hand, according to one implementation of the present disclosure, the s-factor of the thin film transistor (100) can be increased while the thin film transistor (100) has excellent ON current characteristics. Since the thin film transistor (100) according to one implementation of the present disclosure has a large s-factor, it can be used as a driving transistor of a display device.

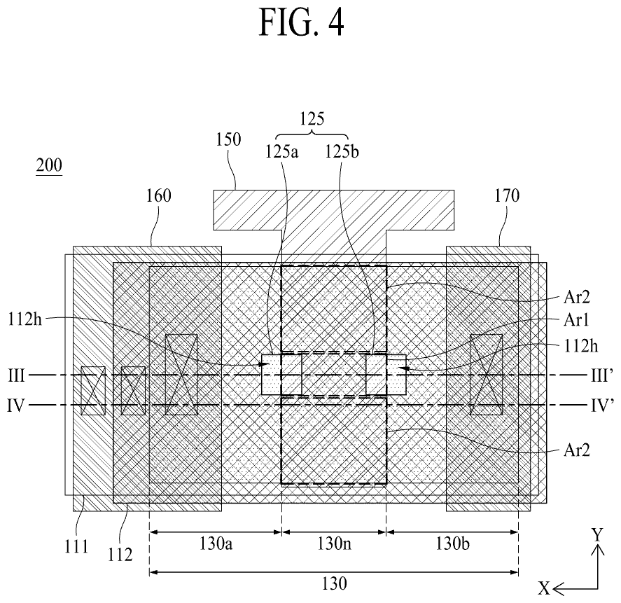

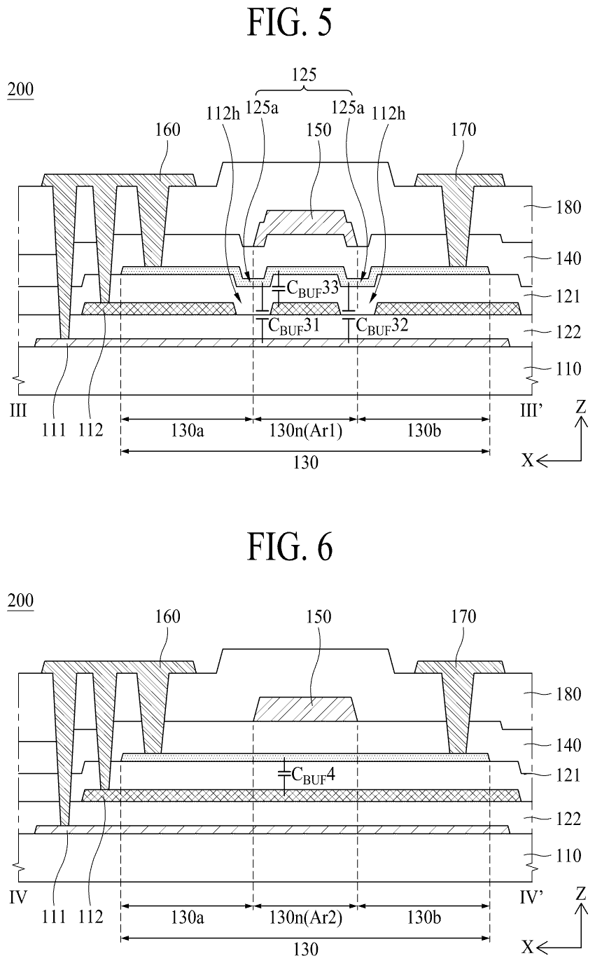

FIG. 4 is a plan view of a thin film transistor (200) according to another implementation of the present disclosure. FIG. 5 is a cross-sectional view taken along line III-III′ of FIG. 4. FIG. 6 is a cross-sectional view taken along line IV-IV′ of FIG. 4.

The thin film transistor (200) of FIGS. 4, 5, and 6 further includes a second light shielding layer (112) and a second buffer layer (122) compared to the thin film transistor (100) of FIGS. 1, 2, and 3.

According to one implementation of the present disclosure, the second light shielding layer (112) is disposed on the first light shielding layer (111) and may overlap with the active layer (130). Specifically, the second light shielding layer (112) may overlap with the channel portion (130n) of the active layer (130).

According to one implementation of the present disclosure, since the second light shielding layer (112) is connected to the source electrode (160), the same voltage as the source electrode (160) may be applied to the second light shielding layer (112). Since the second light shielding layer (112) is arranged between the base substrate (110) and the active layer (130), the voltage applied to the second light shielding layer (112) can affect the channel portion (130n).

According to one implementation of the present disclosure, the second light shielding layer (112) can include a hole (112h) that overlaps the trench (125) in a plane view. Specifically, the hole (112h) means an etched region in the second light shielding layer (112). More specifically, the hole (112h) of the second light shielding layer (112) in a plane view is surrounded by the unetched second light shielding layer (112).

Referring to FIGS. 4 and 5, the entire area of the hole (112h) can overlap the trench (125) in a plane view.

According to one implementation of the present disclosure, the second buffer layer (122) may be arranged between the first light shielding layer (111) and the second light shielding layer (112). The second buffer layer (122) blocks impurities such as moisture and oxygen flowing in from the base substrate (110) to protect the active layer (130) and serves to flatten the upper portion of the base substrate (110), and may be formed as a single layer or multiple layers. The second buffer layer (122) may be formed of the same material as the first buffer layer (121), or may be formed of a different material.

In the case of FIGS. 4, 5, and 6, compared to FIGS. 1, 2, and 3, the second region (Ar2) disposed on the trench (125) among the channel portions (130n) is disposed closer to the second light shielding layer (112) compared to the first region (Ar1), so that the effective gate voltage (Veff) in the channel portions (130n) decreases, and the s-factor of the thin film transistor (100) can increase.

Referring to FIGS. 4 and 5, a capacitance (CBUF3) is formed between the first region (Ar1) of the channel portion (130n) and the first light shielding layer (111) and the second light shielding layer (112), and a capacitance (CBUF4) is formed between the second region (Ar1) of the channel portion (130n) and the second light shielding layer (112).

Referring to FIG. 5, the capacitance (CBUF3) between the first region (Ar1) of the channel portion (130n) and the first light shielding layer (111) and the second light shielding layer (112) is formed by the sum of the first capacitance (CBUF31), the second capacitance (CBUF32), and the third capacitance (CBUF33) formed between the first region (Ar1) of the channel portion (130n) and the first light shielding layer (111) or the second light shielding layer (112).

The capacitance (CBUF) between the channel portion (130n) and the first light shielding layer (111) and the second light shielding layer (112) is formed by the sum of the capacitance (CBUF3) between the first region (Ar1) of the channel portion (130n) and the first light shielding layer (111) and the second light shielding layer (112) and the capacitance (CBUF4) between the second region (Ar2) of the channel portion (130n) and the second light shielding layer (112).

According to one implementation of the present disclosure, the capacitance (CBUF4) between the second region (Ar2) of the channel portion (130n) and the second light shielding layer (112) is greater than the capacitance (CBUF3) between the first region (Ar1) of the channel portion (130n) and the first light shielding layer (111) and the second light shielding layer (112). As a result, the effective gate voltage (Veff) in the second region (Ar2) located close to the first light shielding layer (111) and the second light shielding layer (112) in the channel portion (130n) can be significantly reduced.

In other words, the thin film transistor (200) according to one implementation of the present disclosure may have capacitances of different sizes arranged in parallel in the width direction.

Therefore, according to one implementation of the present disclosure, the size of the effective gate voltage (Veff) applied to the second region (Ar2) is smaller than the size of the effective gate voltage (Veff) applied to the first region (Ar1).

According to one implementation of the present disclosure, since the effective gate voltage (Veff) in the second region (Ar2) of the channel portion (130n) is relatively small, the current (IDS) increase speed is delayed in the threshold voltage (Vth) section before the thin film transistor (200) is completely turned on, resulting in an effect of increasing the s-factor. In this way, according to one implementation of the present disclosure, since the first buffer layer (121) has a trench (125) structure, the s-factor of the thin film transistor (200) can be increased without increasing the gap between the channel portion (130n) and the gate electrode (150).

According to one implementation of the present disclosure, since the gap between the channel portion (130n) and the gate electrode (150) is not increased, the ON current of the thin film transistor (200) does not decrease when the thin film transistor (200) is turned on. In particular, the region of the channel portion (130n) arranged in the trench (125) becomes the main current region, so that the ON current characteristics of the thin film transistor (200) can be improved.

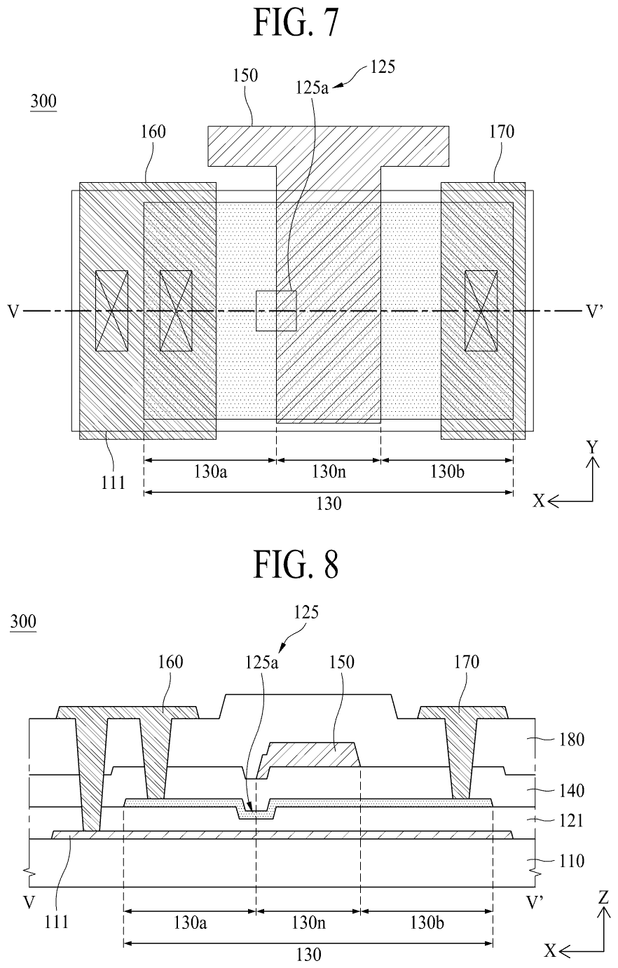

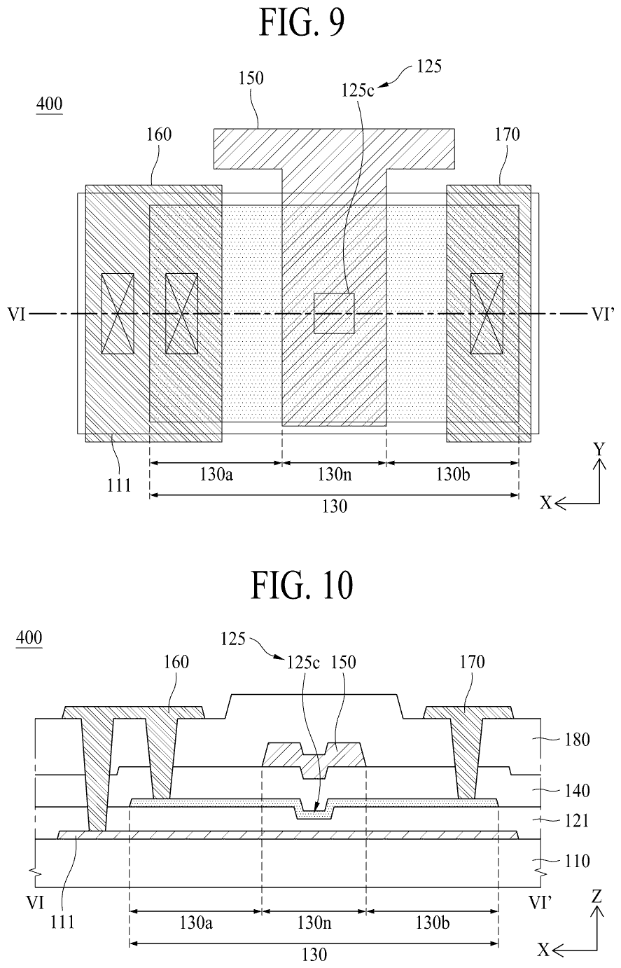

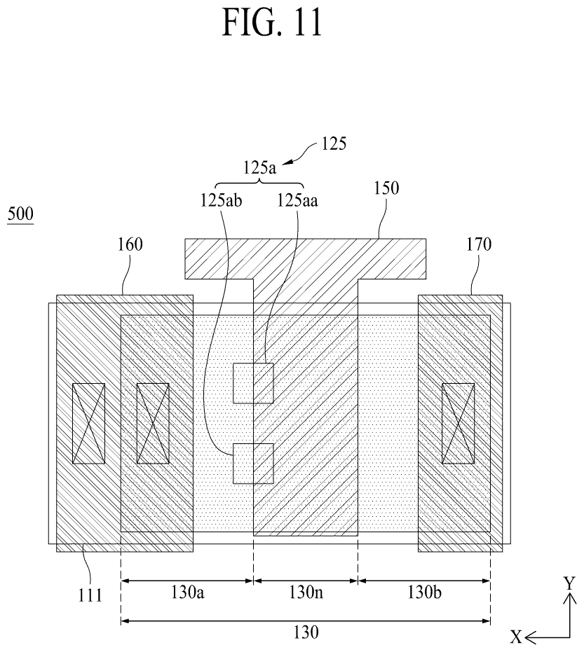

FIG. 7 is a plan view of a thin film transistor (300) according to another implementation of the present disclosure. FIG. 8 is a cross-sectional view taken along line V-V′ of FIG. 7. FIG. 9 is a plan view of a thin film transistor (400) according to another implementation of the present disclosure. FIG. 10 is a cross-sectional view taken along line VI-VI′ of FIG. 9.

According to one implementation of the present disclosure, the trench (125) may include at least one of a first trench (125a) overlapping the first connecting portion (130a) and a second trench (125b) overlapping the second connecting portion (130b).

For example, FIG. 7 and FIG. 8 illustrate a structure in which the trench (125) includes the first trench (125a) and does not include the second trench (125b).

According to one implementation of the present disclosure, the trench (125) may include a second trench (125b) and may not include a first trench (125a).

According to one implementation of the present disclosure, the trench (125) may include both a first trench (125a) and a second trench (125b). At this time, the first trench (125a) and the second trench (125b) may be arranged to be spaced apart from each other. Specifically, the first trench (125a) and the second trench (125b) may have a shape that protrudes from the gate electrode (150) in a plane view.

FIG. 1 illustrates a shape in which the first trench (125a) and the second trench (125b) are arranged to be spaced apart from each other in a plane view with a portion of the channel portion (130n) interposed therebetween.

According to one implementation of the present disclosure, the trench (125) may further include a third trench (125c). Specifically, the third trench (125c) may not overlap the first connecting portion (130a) and the second connecting portion (130b).

FIGS. 9 and 10 illustrate a plan view of the entire area of the third trench (125c) overlapping the gate electrode (150).

FIGS. 9 and 10 illustrate a plan view of the third trench (125c) being arranged at the center of the gate electrode (150). However, one implementation of the present disclosure is not limited thereto, and the third trench (125c) may be arranged to be biased toward either the first connecting portion (130a) or the second connecting portion (130b) in the plan view.

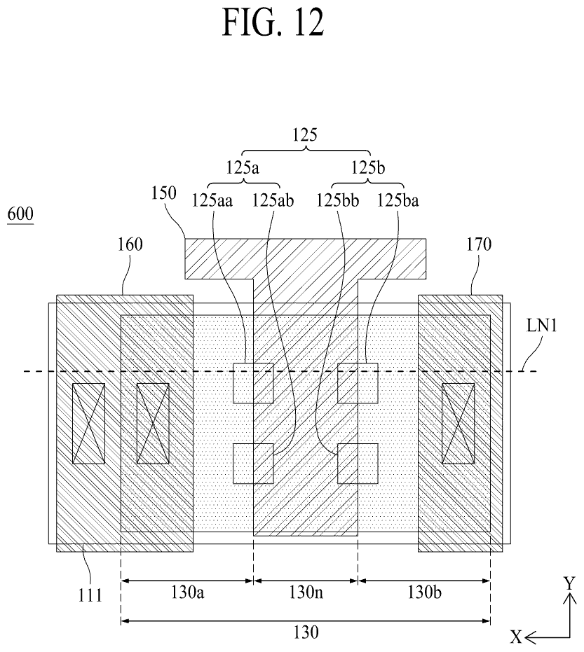

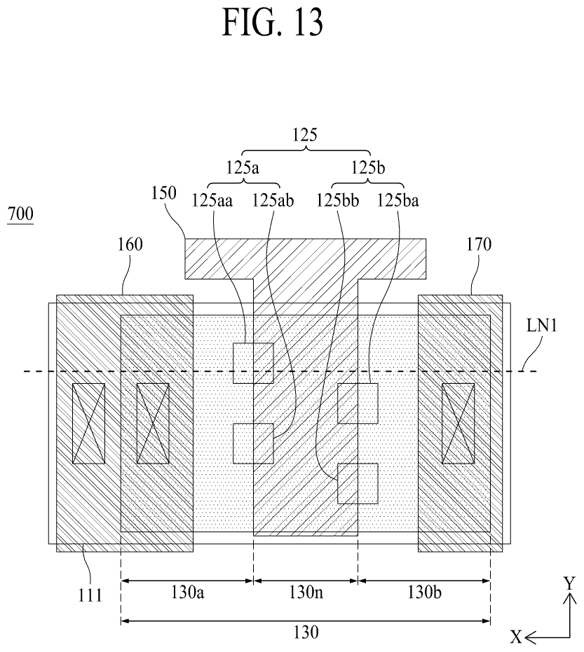

FIG. 11 is a plan view of a thin film transistor (500) according to another implementation of the present disclosure. FIG. 12 is a plan view of a thin film transistor (600) according to another implementation of the present disclosure. FIG. 13 is a plan view of a thin film transistor (700) according to another implementation of the present disclosure.

According to one implementation of the present disclosure, the first trench (125a) may include a first sub-trench (125aa) and a second sub-trench (125ab) that are spaced apart from each other. The second trench (125b) may include a first sub-trench (125ba) and a second sub-trench (125bb) that are spaced apart from each other. In addition, the third trench (125c) may include a first sub-trench (125ca) and a second sub-trench (125cb) that are spaced apart from each other.

FIG. 11 illustrates a view in which the first sub-trench (125aa) and the second sub-trench (125ab) of the first trench (125a) are arranged spaced apart from each other.

Although not shown in the drawing, the trench (125) may include only the first sub-trench (125ba) and the second sub-trench (125bb) of the second trench (125b) that are spaced apart from each other.

Although not shown in the drawing, the trench (125) may include only the first sub-trench (125ca) and the second sub-trench (125cb) of the third trench (125c).

FIG. 12 illustrates a trench (125) that includes the first trench (125a) and the second trench (125b), and the first sub-trench (125aa, 125ba) and the second sub-trench (125ab, 125bb) of the first trench (125a) and the second trench (125b) that are spaced apart from each other.

Specifically, an arbitrary straight line (LN1) parallel to the first direction (X) and passing through the first trench (125a) can pass through the second trench (125b).

More specifically, FIG. 12 illustrates a state in which first sub-trench (125aa, 125ba) are arranged in parallel in the first direction (X) and second sub-trench (125ab, 125bb) are arranged in parallel.

FIG. 13 illustrates a state in which a trench (125) includes a first trench (125a) and a second trench (125b), and first sub-trench (125aa, 125ba) and second sub-trench (125ab, 125bb) of the first trench (125a) and the second trench (125b) are arranged spaced apart from each other.

Specifically, an arbitrary straight line (LN1) parallel to the first direction (X) and passing through the first trench (125a) may not pass through the second trench (125b).

More specifically, FIG. 13 illustrates a state in which the first sub-trench (125aa, 125ba) is spaced apart and the second sub-trench (125ab, 125bb) is spaced apart in the first direction (X). That is, the first sub-trench (125aa, 125ba) and the second sub-trench (125ab, 125bb) may be arranged in a zigzag shape.

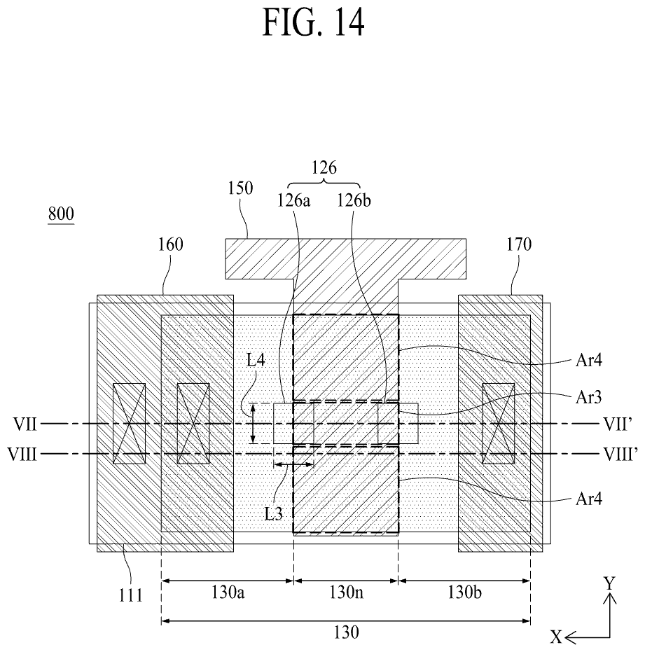

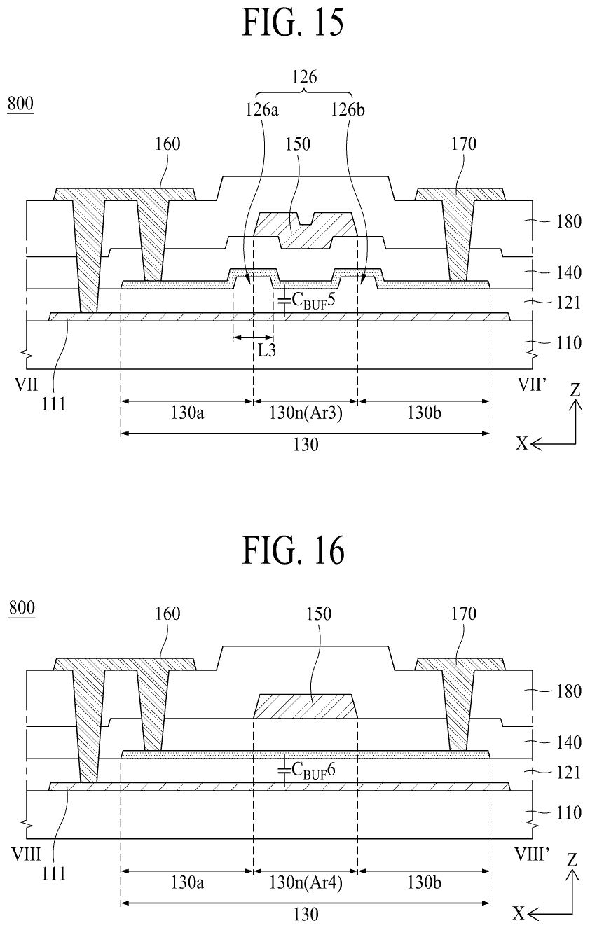

FIG. 14 is a plan view of a thin film transistor (800) according to another implementation of the present disclosure. FIG. 15 is a cross-sectional view taken along line VII-VII′ of FIG. 14. FIG. 16 is a cross-sectional view taken along line VIII-VIII′ of FIG. 13.

Descriptions of components that overlap with those of the thin film transistor (100) illustrated in FIGS. 1, 2, and 3 are omitted. Specifically, descriptions of the base substrate (110), the first light shielding layer (111), the active layer (130), the gate insulating film (140), the gate electrode (150), the source electrode (160), the drain electrode (170), and the interlayer insulating film (180) overlap with those of the thin film transistor (100) illustrated in FIGS. 1, 2, and 3 and are therefore omitted.

Below, the protrusion (126) of the first buffer layer (121) is described in detail.

According to one implementation of the present disclosure, the first buffer layer (121) includes a protrusion (126) that overlaps at least a portion of the gate electrode (150) in a plane view.

FIG. 14 illustrates an example in which the protrusion (126) overlaps at least a portion of the gate electrode (150) in a plane view.

According to one implementation of the present disclosure, the protrusion (126) means an area that is not etched in the first buffer layer (121), an area that is surrounded by an etched first buffer layer (121) among the first buffer layer (121) in a plane view, or an area in which the upper surface of the first buffer layer (121) is positioned farther away from the upper surface of the base substrate (110) compared to other areas of the first buffer layer (121) among the first buffer layer (121).

Descriptions of the first direction (X) and the second direction (Y) are redundant and are omitted.

According to one implementation of the present disclosure, the protrusion (126) may have a length (L3) of 1 μm or more based on the first direction (X). In addition, it may have a width (L4) of 1 μm or more based on the second direction (Y).

Referring to FIG. 14, the protrusion (126) may have a length (L3) of 1 μm or more based on the first direction (X) and a width (L4) of 1 μm or more based on the second direction (Y).

The length (L3) means the maximum length of the protrusion (126) based on the first direction (X), and the width (L4) means the maximum width of the protrusion (126) based on the second direction (Y).

In FIG. 15, the length (L3) of the protrusion (126) is illustrated, and the length (L3) is measured based on the lowermost ends on the left and right sides of the protrusion (126). Although the width (L4) of the protrusion (126) is not shown in the drawing, the width (L4) of the protrusion (126) is also measured based on the lowermost ends on the left and right sides in the cross section, just like the length (L3).

In FIG. 14, the protrusion (126) is illustrated as having a rectangular shape in a plan view. However, one implementation of the present disclosure is not limited thereto, and may have a shape such as a polygon, a circle, or a bow.

According to one implementation of the present disclosure, one of the arbitrary straight lines parallel to the first direction (X) within the area occupied by the active layer (130) in a plan view may intersect with the protrusion (126), and the other of the arbitrary straight lines parallel to the first direction (X) within the area occupied by the active layer (130) in a plan view may not intersect with the protrusion (126).

For example, referring to FIGS. 14, 15, and 16, a straight line corresponding to an extension of VII-VII′ among straight lines parallel to the first direction (X) intersects with the protrusion (126). On the other hand, a straight line corresponding to an extension of VIII-VIII′ among straight lines parallel to the first direction (X) does not intersect with the protrusion (126).

Specifically, among any straight lines parallel to the first direction (X), a straight line intersecting with the protrusion (126) and a straight line not intersecting with the protrusion (126) are arranged side by side along the second direction (Y).

According to one implementation of the present disclosure, the channel portion (130n) includes a third region (Ar3) overlapping with the protrusion (126) and a fourth region (Ar4) not overlapping with the protrusion (126).

The third region (Ar3) and the fourth region (Ar4) may extend from the first connecting portion (130a) to the second connecting portion (130b). Specifically, the third region (Ar3) and the fourth region (Ar4) contact the first connecting portion (130a) and the second connecting portion (130b), respectively. More specifically, the third region (Ar3) and the fourth region (Ar4) may extend from the first connecting portion (130a) to the second connecting portion (130b) based on the first direction (X).

Referring to FIG. 15, a portion of the third region (Ar3) of the channel portion (130n) is disposed on the protrusion (126).

Referring to FIG. 16, the fourth region (Ar4) of the channel portion (130n) is not disposed on the protrusion (126).

According to one implementation of the present disclosure, the active layer (130) is disposed on the protrusion (126). Specifically, the active layer (130) disposed on the protrusion (126) is formed along the upper surface of the protrusion (126).

According to one implementation of the present disclosure, the distance between the upper surface of the base substrate (110) and the upper surface of the active layer (130) overlapping the protrusion (126) is longer than the distance between the upper surface of the base substrate (110) and the upper surface of the active layer (130) that does not overlap the protrusion (126).

In FIG. 15, the distance between the upper surface of the base substrate (110) and the upper surface of the active layer (130) overlapping the protrusion (126) is longer than the distance between the upper surface of the base substrate (110) and the upper surface of the active layer (130) that does not overlap the protrusion (126).

FIG. 16 illustrates an example in which a protrusion (126) is not arranged. The distance between the upper surface of the active layer (130) illustrated in FIG. 16 and the upper surface of the base substrate (110) is the same as the distance between the upper surface of the active layer (130) and the base substrate (110) that does not overlap the protrusion (126) illustrated in FIG. 15.

The explanation of the reduction of the electric field effect by the first light shielding layer (111) and the explanation of the s-factor are omitted because they are redundant.

In the case of FIGS. 14, 15 and 16, compared to FIGS. 1, 2 and 3, the first buffer layer (121) includes a protrusion (126). Since the fourth region (Ar4) not disposed on the protrusion (126) among the channel portions (130n) is disposed closer to the first light shielding layer (111) compared to the third region (Ar3), the effective gate voltage (Veff) in the channel portions (130n) decreases, so that the s-factor of the thin film transistor (100) can increase.

Referring to FIG. 14 and FIG. 15, a capacitance (CBUF5) may be formed between the third region (Ar3) of the channel portion (130n) and the first light shielding layer (111), and a capacitance (CBUF6) may be formed between the fourth region (Ar4) of the channel portion (130n) and the first light shielding layer (111).

The capacitance (CBUF) between the channel portion (130n) and the first light shielding layer (111) is formed by the sum of the capacitance (CBUF5) between the third region (Ar3) of the channel portion (130n) and the first light shielding layer (111) and the capacitance (CBUF6) between the fourth region (Ar4) of the channel portion (130n) and the first light shielding layer (111).

According to one implementation of the present disclosure, the capacitance (CBUF6) between the fourth region (Ar4) of the channel portion (130n) and the first light shielding layer (111) is greater than the capacitance (CBUF5) between the third region (Ar3) of the channel portion (130n) and the first light shielding layer (111). As a result, the effective gate voltage (Veff) in the fourth region (Ar4) of the channel portion (130n) located close to the first light shielding layer (111) can be significantly reduced.

In other words, the thin film transistor (800) according to one implementation of the present disclosure can have capacitances of different sizes arranged in parallel in the width direction.

Therefore, according to one implementation of the present disclosure, the size of the effective gate voltage (Veff) applied to the fourth region (Ar4) is smaller than the size of the effective gate voltage (Veff) applied to the third region (Ar3).

According to one implementation of the present disclosure, since the effective gate voltage (Veff) in the fourth region (Ar4) of the channel portion (130n) is relatively small, the current (IDS) increase speed is delayed in the threshold voltage (Vth) section before the thin film transistor (800) is completely turned on, resulting in an effect of increasing the s-factor.

In addition, according to one implementation of the present disclosure, since the effective gate voltage (Veff) in the third region (Ar3) of the channel portion (130n) is relatively large, the thin film transistor (800) can be made to have excellent ON current characteristics while increasing the s-factor of the thin film transistor (800).

According to one implementation of the present disclosure, since the gap between the channel portion (130n) and the gate electrode (150) is not increased, the ON current of the thin film transistor (800) does not decrease when the thin film transistor (800) is turned on. In particular, the region arranged on the protrusion (126) of the channel portion (130n) becomes the main current region, thereby improving the ON current characteristics of the thin film transistor (800).

According to one implementation of the present disclosure, the thin film transistor (800) can be made to have excellent ON current characteristics while increasing the s-factor of the thin film transistor (800). The thin film transistor (800) according to one implementation of the present disclosure can be used as a driving transistor of a display device because it has a large s-factor.

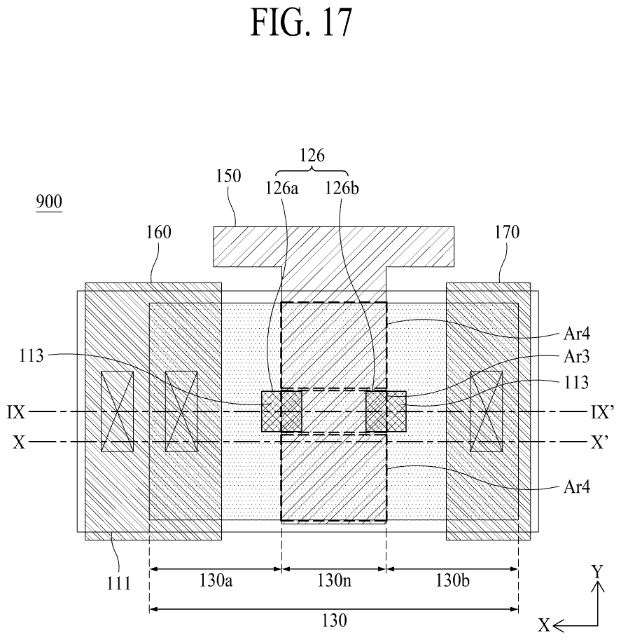

The thin film transistor (900) of FIGS. 17, 18, and 19 further includes a third light shielding layer (113) and a second buffer layer (122) compared to the thin film transistor (800) of FIGS. 14, 15, and 16.

According to one implementation of the present disclosure, the third light shielding layer (113) is disposed on the first light shielding layer (111) and can overlap with the active layer (130). Specifically, the third light shielding layer (113) can overlap with the channel portion (130n) of the active layer (130).

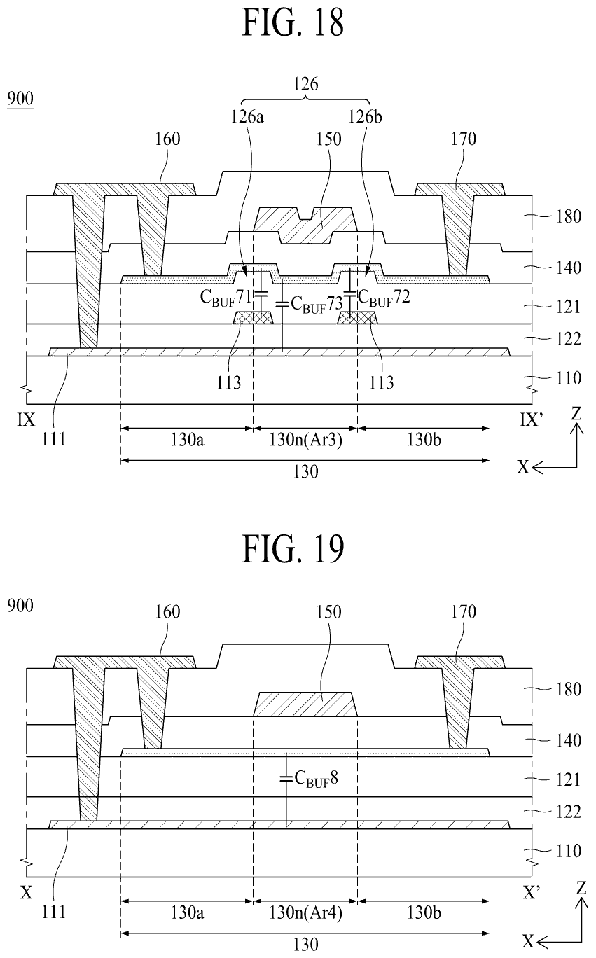

According to one implementation of the present disclosure, the third light shielding layer (113) can overlap with the protrusion (126). In FIG. 17 and FIG. 18, the entire area of the third light shielding layer (113) can overlap with the protrusion (126).

According to one implementation of the present disclosure, since the third light shielding layer (113) is connected to the source electrode (160), the same voltage as the source electrode (160) can be applied to the third light shielding layer (113). Since the third light shielding layer (113) is arranged between the base substrate (110) and the active layer (130), the voltage applied to the third light shielding layer (113) can affect the channel portion (130n).

According to one implementation of the present disclosure, the second buffer layer (122) is disposed between the base substrate (110) and the active layer (130). Specifically, the second buffer layer (122) is disposed between the first light shielding layer (111) and the third light shielding layer (113).

The description of the second buffer layer (122) is omitted due to redundancy.

In the case of FIGS. 17, 18, and 19, compared to FIGS. 14, 15, and 16, the third region (Ar3) disposed on the protrusion (126) among the channel portions (130n) is disposed adjacent to the third light shielding layer (113) compared to the fourth region (Ar4) not disposed on the protrusion (126), so that the effective gate voltage (Veff) in the channel portion (130n) decreases, and the s-factor of the thin film transistor (900) can increase.

Referring to FIG. 17 and FIG. 18, a capacitance (CBUF7) is formed between the third region (Ar3) of the channel portion (130n) and the first light shielding layer (111) and the third light shielding layer (113), and a capacitance (CBUF8) is formed between the fourth region (Ar4) of the channel portion (130n) and the first light shielding layer (111).

Referring to FIG. 18, the capacitance (CBUF7) between the third region (Ar3) of the channel portion (130n) and the first light shielding layer (111) and the third light shielding layer (113) is formed by the sum of the first capacitance (CBUF71), the second capacitance (CBUF72), and the third capacitance (CBUF73) formed between the third region (Ar3) of the channel portion (130n) and the first light shielding layer (111) or the third light shielding layer (113).

The capacitance (CBUF) between the channel portion (130n) and the first light shielding layer (111) and the third light shielding layer (113) is formed by the sum of the capacitance (CBUF7) between the third region (Ar3) of the channel portion (130n) and the first light shielding layer (111) and the third light shielding layer (113) and the capacitance (CBUF8) between the fourth region (Ar4) of the channel portion (130n) and the first light shielding layer (111).

According to one implementation of the present disclosure, the capacitance (CBUF7) between the third region (Ar3) of the channel portion (130n) and the first light shielding layer (111) and the third light shielding layer (113) is greater than the capacitance (CBUF8) between the fourth region (Ar4) of the channel portion (130n) and the first light shielding layer (111). As a result, the effective gate voltage (Veff) in the third region (Ar3) located close to the first light shielding layer (111) and the third light shielding layer (113) in the channel portion (130n) can be significantly reduced.

In other words, the thin film transistor (900) according to one implementation of the present disclosure can have capacitances of different sizes arranged in parallel in the width direction.

Therefore, according to one implementation of the present disclosure, the size of the effective gate voltage (Veff) applied to the third region (Ar3) is smaller than the size of the effective gate voltage (Veff) applied to the fourth region (Ar4).

According to one implementation of the present disclosure, since the effective gate voltage (Veff) in the third region (Ar3) of the channel portion (130n) is relatively small, the current (IDS) increase speed is delayed in the threshold voltage (Vth) section before the thin film transistor (900) is completely turned on, resulting in an effect of increasing the s-factor. In this way, according to one implementation of the present disclosure, since the first buffer layer (121) includes the protrusion (126), and the thin film transistor (900) includes the third light shielding layer (113) overlapping the protrusion (126), the s-factor of the thin film transistor (900) can be increased without increasing the gap between the channel portion (130n) and the gate electrode (150).

According to one implementation of the present disclosure, since the gap between the channel portion (130n) and the gate electrode (150) is not increased, the ON current of the thin film transistor (900) is not reduced when the thin film transistor (900) is turned on. In particular, the area of the channel portion (130n) that is not arranged in the protrusion (126) becomes the main current area, so that the ON current characteristics of the thin film transistor (900) can be improved.

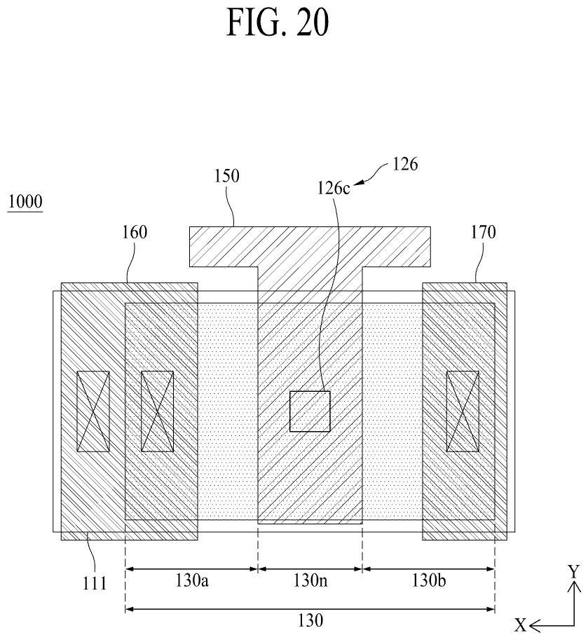

FIG. 20 is a plan view of a thin film transistor (1000) according to another implementation of the present disclosure.

According to an implementation of the present disclosure, the protrusion (126) may include at least one of a first protrusion (126a) overlapping the first connecting portion (130a) and a second protrusion (126b) overlapping the second connecting portion (130b).

Although not shown in the drawing, according to an implementation of the present disclosure, the protrusion (126) may include the first protrusion (126a) and may not include the second protrusion (126b).

Although not shown in the drawing, according to an implementation of the present disclosure, the protrusion (126) may include the second protrusion (126b) and may not include the first protrusion (126a).

According to an implementation of the present disclosure, the protrusion (126) may include both the first protrusion (126a) and the second protrusion (126b). At this time, the first protrusion (126a) and the second protrusion (126b) may be arranged spaced apart from each other. Specifically, the first protrusion (126a) and the second protrusion (126b) may have a shape protruding from the gate electrode (150) in a plane view.

FIG. 14 illustrates a state in which the first protrusion (126a) and the second protrusion (126b) are arranged spaced apart from each other with a portion of the channel portion (130n) interposed therebetween in a plane view.

According to one implementation of the present disclosure, the protrusion (126) may further include a third protrusion (126c). Specifically, the third protrusion (126c) may not overlap the first connecting portion (130a) and the second connecting portion (130b).

FIG. 20 illustrates a state in which the entire area of the third protrusion (126c) overlaps the gate electrode (150) in a plane view.

FIG. 20 illustrates a third protrusion (126c) being arranged in the center of the gate electrode (150) in a plane view. However, one implementation of the present disclosure is not limited thereto, and the third protrusion (126c) may be arranged with a bias toward either the first connecting portion (130a) or the second connecting portion (130b) in a plane view.

According to one implementation of the present disclosure, the first protrusion (126a) may include a first sub-protrusion (126aa) and a second sub-protrusion (126ab) that are spaced apart from each other. The second protrusion (126b) may include a first sub-protrusion (126ba) and a second sub-protrusion (126bb) that are spaced apart from each other. In addition, the third protrusion (126c) may include a first sub-protrusion (126ca) and a second sub-protrusion (126cb) that are spaced apart from each other. At this time, the first sub-protrusion (126aa) and the second sub-protrusion (126ab) of the first protrusion (126a), the first sub-protrusion (126ba) and the second sub-protrusion (126bb) of the second protrusion (126b) may have a similar arrangement structure to the first sub-trench (125aa) and the second sub-trench (125ab) of the first trench (125a), and the first sub-trench (125ba) and the second sub-trench (125bb) of the second trench (125b) as shown in FIGS. 12 and 13 in terms of plan view.

Although not shown in the drawing, the protrusion (126) may include only the first sub-protrusion (126aa) and the second sub-protrusion (126ab) of the first protrusion (126a) that are spaced apart from each other.

Although not shown in the drawing, the protrusion (126) may include only the first sub-protrusion (126ba) and the second sub-protrusion (126bb) of the second protrusion (126b) that are spaced apart from each other.

Although not shown in the drawing, the protrusion (126) may include only the first sub-protrusion (126ca) and the second sub-protrusion (126cb) of the third protrusion (126c).

Although not shown in the drawing, the protrusion (126) may include the first protrusion (126a) and the second protrusion (126b), and the first sub-protrusions (126aa, 126ba) and the second sub-protrusions (126ab, 126bb) of the first protrusion (126a) and the second protrusion (126b) that are spaced apart from each other may be arranged. This appearance may have a similar arrangement structure that is the same as the plan view illustrated in FIG. 12.

Specifically, an arbitrary straight line (LN2, not shown) that is parallel to the first direction (X) and passes through the first protrusion (126a) may pass through the second protrusion (126b).

More specifically, the first sub-protrusions (126aa, 126ba) may be arranged in parallel in the first direction (X), and the second sub-protrusions (126ab, 126bb) may be arranged in parallel.

Although not shown in the drawing, the protrusion (126) may include the first protrusion (126a) and the second protrusion (126b), and the first sub-protrusions (126aa, 126ba) and the second sub-protrusions (126ab, 126bb) of the first protrusion (126a) and the second protrusion (126b) may be arranged spaced apart from each other. This appearance may have a similar arrangement structure to the plan view illustrated in FIG. 13.

Specifically, any straight line (LN2, not shown) that is parallel to the first direction (X) and passes through the first protrusion (126a) may not pass through the second protrusion (126b).

More specifically, the first sub-protrusions (126aa, 126ba) may be spaced apart and arranged in the first direction (X), and the second sub-protrusions (126ab, 126bb) may be spaced apart and arranged. That is, the first sub-protrusions (126aa, 126ba) and the second sub-protrusions (126ab, 126bb) may be arranged in a zigzag shape.

FIGS. 21A and 21B are schematic diagrams explaining the effective gate voltage of a thin film transistor. FIGS. 21C and 21D are schematic diagrams explaining the effective gate voltage of a thin film transistor according to one implementation of the present disclosure.

Descriptions of FIGS. 21A, 21B, 21C, and 21D are omitted because they are redundant.

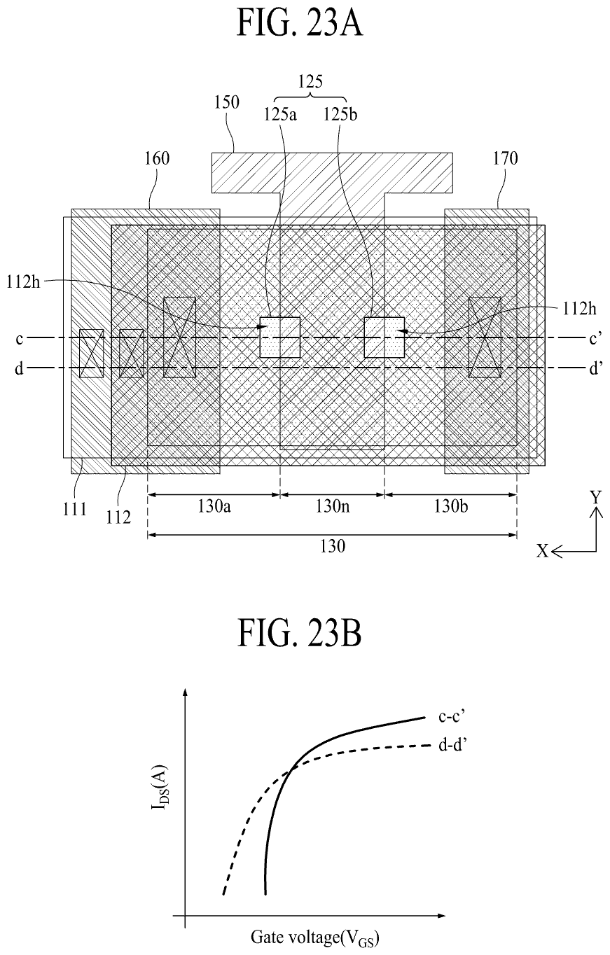

FIG. 22A is a plan view of a thin film transistor according to an implementation. FIG. 22B is a graph showing current characteristics in the thin film transistor according to FIG. 22A. FIG. 23A is a plan view of a thin film transistor according to another implementation. FIG. 23B is a graph showing current characteristics in the thin film transistor according to FIG. 23A.

The thin film transistor of FIG. 22A corresponds to the thin film transistor (100) of FIG. 1, and the thin film transistor of FIG. 23A corresponds to the thin film transistor (200) of FIG. 4.

In the graphs of FIGS. 22B and 23B, the horizontal axis represents the gate voltage (VGS), and the vertical axis represents the drain-source current (IDS).

The a-a′ graph of FIG. 22B is a graph showing the current characteristics in the region corresponding to a-a′ of FIG. 22A, and the b-b′ graph is a graph showing the current characteristics in the region corresponding to b-b′ of FIG. 22A.

In the a-a′ region of FIG. 22A, due to the arrangement of the trench (125), the channel portion (130n) overlapping the trench (125) is arranged close to the first light shielding layer (111). As a result, the effective gate voltage (Veff) applied to the channel portion (130n) is reduced, so that the s-factor of the thin film transistor can increase.

In the b-b′ region of FIG. 22A, since the trench (125) is not arranged, the channel portion (130n) is arranged farther away from the first light shielding layer (111) compared to the a-a′ region. Due to this, the effective gate voltage (Veff) applied to the channel portion (130n) is not significantly reduced, so that the s-factor of the thin film transistor may not increase compared to the a-a′ region, and the ON current characteristics of the thin film transistor may be improved.

Therefore, the s-factor of the thin film transistor can be increased due to the trench (125) arranged in the a-a′ region of FIG. 22A, and the ON current characteristic of the thin film transistor can be improved because the trench (125) is not arranged in the b-b′ region. As a result, the thin film transistor according to one implementation of the present disclosure can have a large s-factor and excellent current characteristics in the ON state.

In FIG. 23B, the c-c′ graph is a graph showing the current characteristics in the region corresponding to c-c′ of FIG. 23A, and the d-d′ graph is a graph showing the current characteristics in the region corresponding to d-d′ of FIG. 23A.

In the c-c′ region of FIG. 23A, a second light shielding layer (112) having a hole (112h) overlapping with the trench (125) is arranged, compared to FIG. 22A, so that the channel portion (130n) overlapping with the trench (125) is arranged far from the first light shielding layer (111). As a result, the effective gate voltage (Veff) applied to the channel portion (130n) is not greatly reduced, so that the s-factor of the thin film transistor may not increase compared to the d-d′ region, and the ON current characteristics of the thin film transistor may be improved.

In the d-d′ region of FIG. 23A, the trench (125) is not arranged, and the second light shielding layer (112) is arranged, so that the channel portion (130n) is arranged close to the second light shielding layer (112). Due to this, the effective gate voltage (Veff) applied to the channel portion (130n) is reduced, so that the s-factor of the thin film transistor can increase.

Therefore, since the trench (125) is not arranged in the d-d′ region of FIG. 23A, the s-factor of the thin film transistor can increase, and since the second light shielding layer (112) having the trench (125) and the hole (112h) is arranged in the c-c′ region, the ON current characteristic of the thin film transistor can be improved. As a result, the thin film transistor according to one implementation of the present disclosure can have a large s-factor and excellent current characteristics in the ON state.

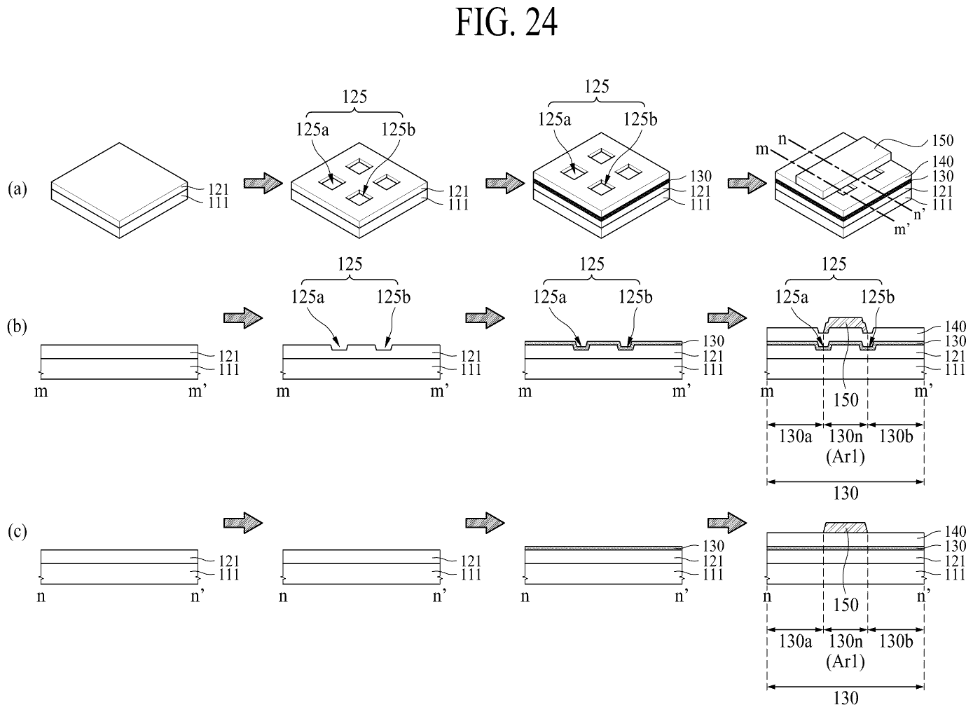

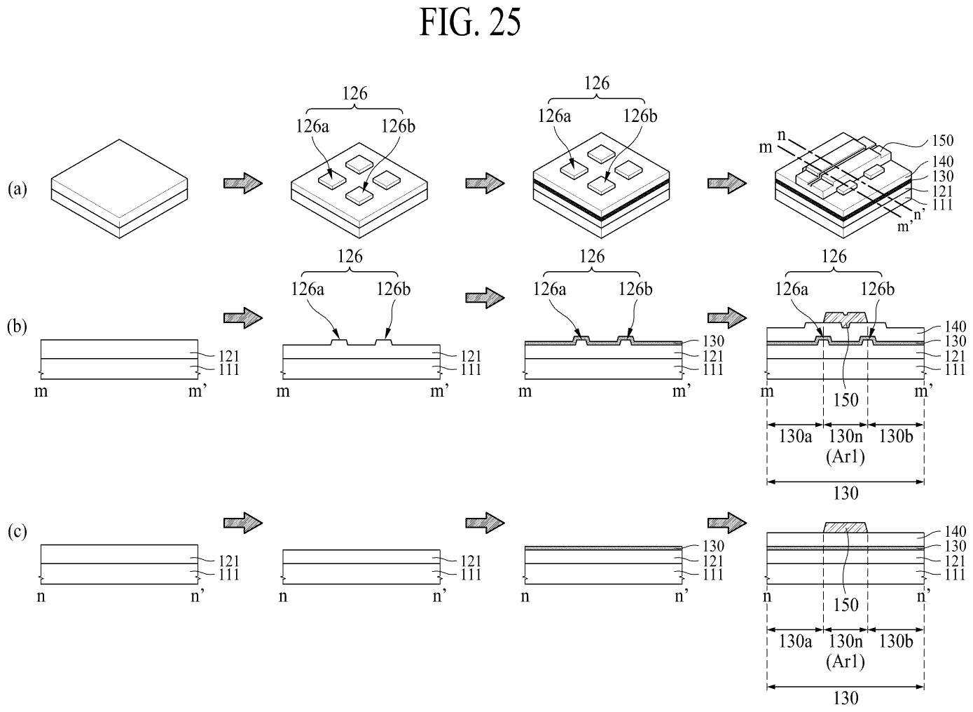

FIG. 24 is a process diagram showing a method for manufacturing a thin film transistor according to one implementation of the present disclosure. FIG. 25 is a process diagram showing a method for manufacturing a thin film transistor according to another implementation of the present disclosure.

According to FIG. 24, (a) shows a perspective view of a manufacturing process of a thin film transistor according to an implementation of the present disclosure, (b) shows a cross-sectional view of (a) cut along the m-m′ line, and (c) shows a cross-sectional view of (a) cut along the n-n′ line.

Specifically, (b) of FIG. 24 shows the formation process of the cross-sectional view shown in FIG. 2, and (c) of FIG. 24 shows the formation process of the cross-sectional view shown in FIG. 3.

The first drawing of FIG. 24 shows a scene in which a first light shielding layer (111) is formed and a first buffer layer (121) is formed on the first light shielding layer (111).

The second drawing of FIG. 24 shows a scene in which a part of the first buffer layer (121) is etched to form a trench (125).

The third drawing of FIG. 24 shows a scene in which an active layer (130) is formed on the first buffer layer (121).

The fourth drawing of FIG. 24 illustrates a process of forming a gate insulating film (140) on an active layer (130) and forming a gate electrode (150) on the gate insulating film (140).

The manufacturing process illustrated in FIG. 24 corresponds to the manufacturing process of the thin film transistor (100) illustrated in FIGS. 1 to 3. The manufacturing process of FIG. 24 omits the steps of forming the base substrate (110), the source electrode (160), the drain electrode (170), and the interlayer insulating film (180) described in FIGS. 1 to 3. The description of the configuration illustrated in FIG. 24 is omitted because it overlaps with the description of the configuration illustrated in FIGS. 1 to 3.

According to FIG. 25, (a) shows a perspective view of a manufacturing process of a thin film transistor according to an implementation of the present disclosure, (b) shows a cross-sectional view of (a) cut along the m-m′ line, and (c) shows a cross-sectional view of (a) cut along the n-n′ line.

Specifically, (b) of FIG. 25 shows the formation process of the cross-sectional view illustrated in FIG. 15, and (c) of FIG. 25 shows the formation process of the cross-sectional view illustrated in FIG. 16.

The first drawing of FIG. 25 shows the formation of the first light shielding layer (111) and the formation of the first buffer layer (121) on the first light shielding layer (111).

The second drawing of FIG. 25 shows the formation of a protrusion (126) by etching a part of the first buffer layer (121).

The third drawing of FIG. 25 shows the formation of the active layer (130) on the first buffer layer (121).

The fourth drawing of FIG. 25 shows the formation of the gate insulating film (140) on the active layer (130) and the formation of the gate electrode (150) on the gate insulating film (140).

The manufacturing process illustrated in FIG. 25 corresponds to the manufacturing process of the thin film transistor (800) illustrated in FIGS. 14 to 16. The manufacturing process of FIG. 25 omits the steps of forming the base substrate (110), the source electrode (160), the drain electrode (170), and the interlayer insulating film (180) described in FIGS. 14 to 16. The description of the configuration illustrated in FIG. 25 is omitted because it overlaps with the description of the configuration illustrated in FIGS. 14 to 16.

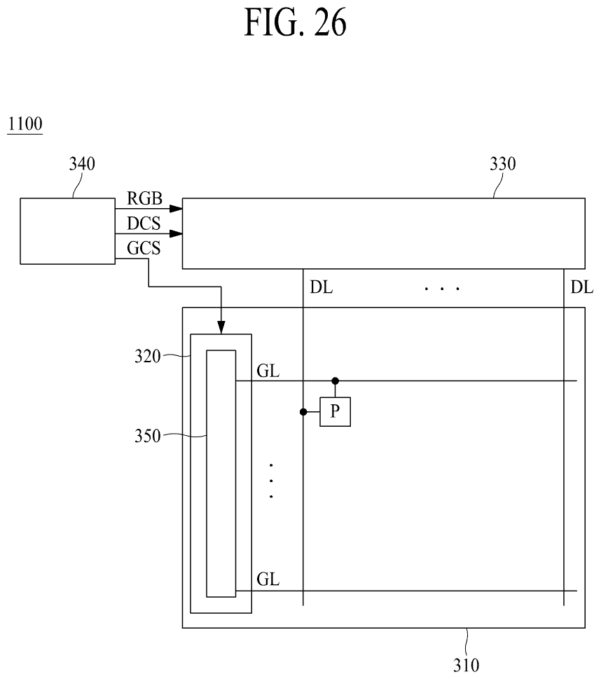

FIG. 26 is a schematic diagram illustrating a display apparatus 1100 according to further still another implementation of the present disclosure.

As shown in FIG. 26, the display apparatus 1100 according to further still another implementation of the present disclosure may include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one implementation of the present disclosure, the gate driver 320 may be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 may be disposed on the base substrate 110.

The display apparatus 1100 according to one implementation of the present disclosure may include the above-described thin film transistors 100, 200, 300, 400, 500, 600, 700, 800, 900 and 1000. According to one implementation of the present disclosure, the gate driver 320 may include the above-described thin film transistors 100, 200, 300, 400, 500, 600, 700, 800, 900 and 1000.

The gate driver 320 may include a shift register 350.

The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 may include the above-described thin film transistors 100, 200, 300, 400, 500, 600, 700, 800, 900 and 1000.

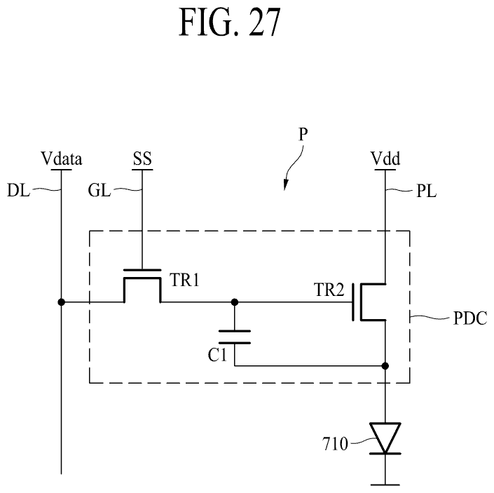

FIG. 27 is a circuit view illustrating any one pixel P of FIG. 26.

The circuit view of FIG. 27 is an equivalent circuit view for the pixel P of the display apparatus 1100 that includes an organic light emitting diode (OLED) as a display element 710.

Referring to FIG. 27, the pixel P includes a display element 710 and a pixel driving circuit PDC for driving the display element 710. In detail, the display apparatus 1100 according to one implementation of the present disclosure may include a pixel driving circuit PDC on the base substrate 110.

The pixel driving circuit PDC of FIG. 27 includes a first thin film transistor TRI that is a switching transistor and a second thin film transistor TR2 that is a driving transistor. The display apparatus 1100 according to another implementation of the present disclosure may include at least one of the above-described thin film transistors 100, 200, 300, 400, 500, 600, 700, 800, 900 and 1000.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

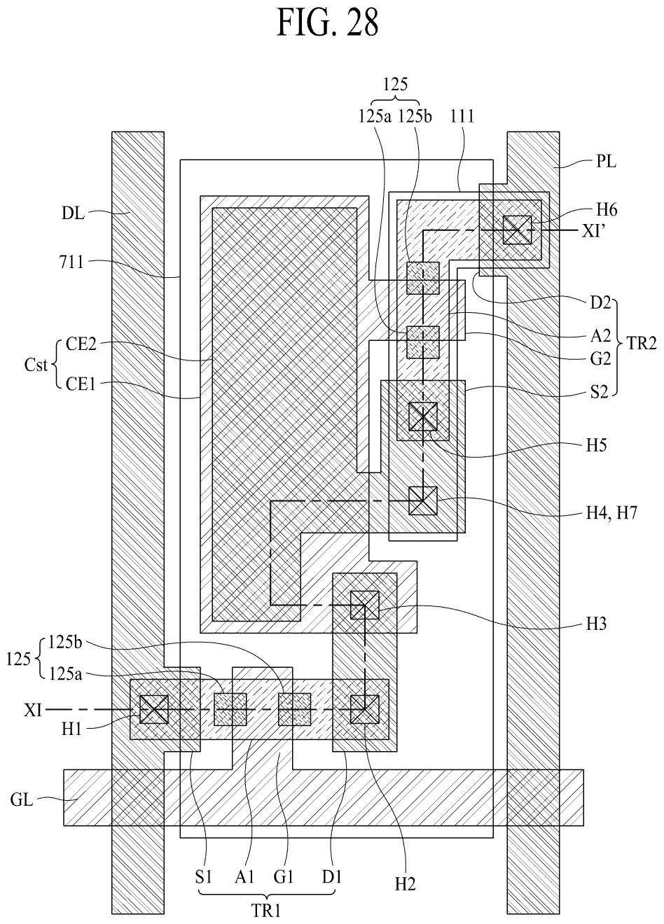

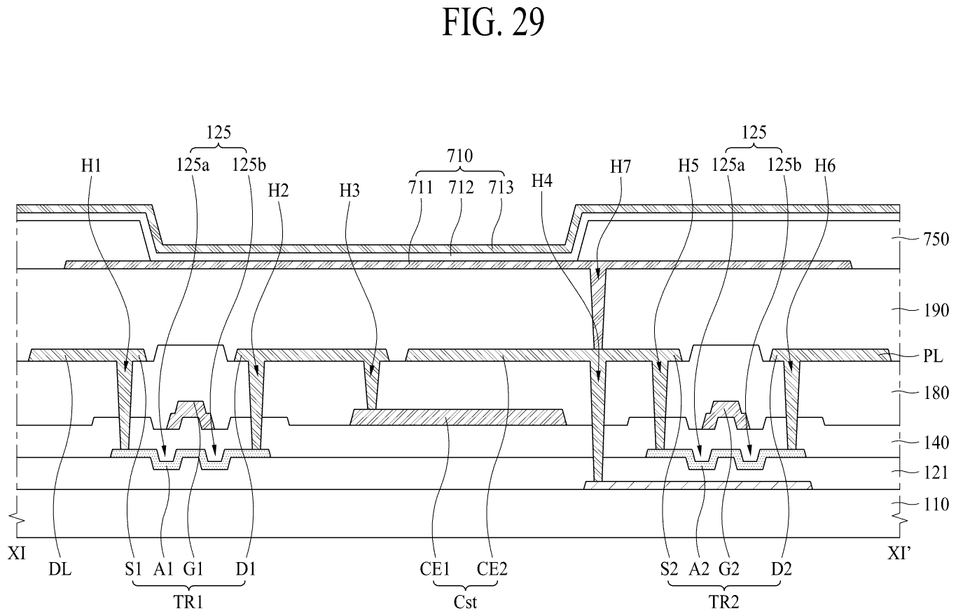

FIG. 28 is a plan view of the pixel of FIG. 27, and FIG. 29 is a cross-sectional view taken along line XI-XI′ of FIG. 28.

Referring to FIG. 28 and FIG. 29, a first thin film transistor (TR1) and a second thin film transistor (TR2) are disposed on a base substrate (110).

The base substrate (110) may be made of glass or plastic. A plastic having flexible properties, such as polyimide (PI), may be used as the base substrate (110).

A light shielding layer (111) is disposed on the base substrate (110). The light shielding layer (111) may have light shielding properties. The light shielding layer (111) may block light incident from the outside to protect the active layers (A1, A2).

A first buffer layer (121) is disposed on the first light shielding layer (111). The first buffer layer (121) is made of an insulating material and protects the active layers (A1, A2) from moisture or oxygen flowing in from the outside.

The first buffer layer (121) includes a trench (125) having a first trench (125a) and a second trench (125b). The trench (125) overlaps at least a portion of the gate electrodes (G1, G2).

An active layer (A1) of a first thin film transistor (TR1) and an active layer (A2) of a second thin film transistor (TR2) are arranged on the first buffer layer (121).

The active layers (A1, A2) may include, for example, an oxide semiconductor material. The active layers (A1, A2) may have a multilayer structure made of an oxide semiconductor material.

A gate insulating film (140) is arranged on the active layers (A1, A2). The gate insulating film (140) covers the upper surface of the active layer (A1, A2).

A gate electrode (G1) of a first thin film transistor (TR1) and a gate electrode (G2) of a second thin film transistor (TR2) are disposed on the gate insulating film (140).

Although not shown in the drawing, a gate line (GL) may be disposed on the gate insulating film (140). The gate electrode (G1) of the first thin film transistor (TR1) may extend from the gate line (GL) or may be a part of the gate line (GL).

Referring to FIG. 28 and FIG. 29, a first capacitor electrode (CE1) of a storage capacitor (Cst) is formed on a gate insulating film (140). The first capacitor electrode (CE1) may be formed using the same material as the gate electrodes (G1, G2) through the same process.

An interlayer insulating film (180) is disposed on the gate electrodes (G1, G2) and the first capacitor electrode (CE1).

A data line (DL) and a driving power line (PL) are disposed on the interlayer insulating film (180). In addition, a source electrode (S1) and a drain electrode (D1) of a first thin film transistor (TR1) are disposed on the interlayer insulating film (180), and a source electrode (S2) and a drain electrode (D2) of a second thin film transistor (TR2) are disposed.

The source electrode (S1) of the first thin film transistor (TR1) may be formed integrally with the data line (DL) and may have a structure extending from the data line (DL).

The source electrode (S1) of the first thin film transistor (TR1) may contact a side surface of the active layer (A1) of the first thin film transistor (TR1) through the first contact hole (H1).

The drain electrode (D1) of the first thin film transistor (TR1) may contact the other side surface of the active layer (A1) of the first thin film transistor (TR1) through the second contact hole (H2). In addition, the drain electrode (D1) of the first thin film transistor (TR1) is connected to the first capacitor electrode (CE1) through the third contact hole (H3). As a result, the first capacitor electrode (CE1) may be connected to the first thin film transistor (TR1).

The drain electrode (D2) of the second thin film transistor (TR1) may be formed integrally with the driving power line (PL) and may have a structure extending from the driving power line (PL).

The drain electrode (D2) of the second thin film transistor (TR1) may contact the side of the active layer (A2) of the second thin film transistor (TR2) through the sixth contact hole (H6).

The source electrode (S2) of the second thin film transistor (TR2) contacts the other side of the active layer (A2) of the second thin film transistor (TR2) through the fifth contact hole (H5). In addition, the source electrode (S2) of the second thin film transistor (TR2) is connected to the first light shielding layer (111) through the fourth contact hole (H4). The same voltage as the source electrode (S2) of the second thin film transistor (TR2) may be applied to the first light shielding layer (111) overlapping the second thin film transistor (TR2).

The source electrode (S2) of the second thin film transistor (TR2) may extend onto the interlayer insulating film (180) to form the second capacitor electrode (CE2) of the storage capacitor (Cst).

According to one implementation of the present disclosure, the first capacitor electrode (CE1) and the second capacitor electrode (CE2) may overlap to form the storage capacitor (Cst).

Referring to FIGS. 28 and 29, a planarization layer (190) is disposed on the data line (DL), the driving power line (PL), the source electrodes (S1, S2), the drain electrodes (D1, D2), and the second capacitor electrode (CE2). The planarization layer (190) planarizes the upper portions of the first thin film transistor (TR1) and the second thin film transistor (TR2), and protects the first thin film transistor (TR1) and the second thin film transistor (TR2). The planarization layer (190) functions as a protective layer.

A first electrode (711) of a display element (710) is placed on a planarization layer (190). The first electrode (711) of the display element (710) contacts a second capacitor electrode (CE2) through a seventh contact hole (H7) formed in the planarization layer (190). As a result, the first electrode (711) of the display element (710) can be connected to a source electrode (S2) of a second thin film transistor (TR2).

A bank layer (750) is arranged on the edge of the first electrode (711). The bank layer (750) defines the light-emitting area of the display element (710).

An organic light-emitting layer (712) is arranged on the first electrode (711), and a second electrode (713) is arranged on the organic light-emitting layer (712). Accordingly, the display element (710) is completed. The display element (710) illustrated in FIG. 29 is an organic light-emitting diode (OLED). Therefore, the display device (1100) according to one implementation of the present disclosure is an organic light-emitting display device.

A pixel driving circuit (PDC) according to another implementation of the present disclosure may be formed in various structures other than the structure described above. The pixel driving circuit (PDC) may include, for example, three or more thin film transistors.

According to the present disclosure, the following advantageous effects may be obtained.

A thin film transistor according to one implementation of the present disclosure may have a feature in which capacitances of different sizes are arranged in parallel in the width direction by including a buffer layer having a trench.

A thin film transistor according to one implementation of the present disclosure may have a feature in which capacitances of different sizes are arranged in parallel in the width direction by including a buffer layer having a protrusion.

A thin film transistor according to one implementation of the present disclosure may have a large s-factor and excellent current characteristics in the ON state.

A thin film transistor according to one implementation of the present disclosure may have excellent current characteristics and a large s-factor by controlling the size of the capacitance (Cap) in the width direction of the channel.

It will be apparent that the present disclosure described above is not limited by the above-described implementations and the accompanying drawings and that substitutions, modifications and variations can be made from the disclosed examples while remaining true to the implementations described. Consequently, it is intended that the described implementations include modifications and variations of the disclosed examples.

What is claimed is:

1. A thin film transistor comprising:
a base substrate;
a first light shielding layer on the base substrate;
a first buffer layer on the first light shielding layer;
an active layer on the first buffer layer; and
a gate electrode spaced apart from the active layer and overlapping at least a portion of the active layer,
wherein the active layer includes:
a channel portion overlapping the gate electrode;
a first connecting portion connected to one side of the channel portion; and
a second connecting portion connected to the other side of the channel portion,
wherein the first light shielding layer overlaps the active layer,
the first buffer layer includes a trench overlapping at least a portion of the gate electrode in a plane view,
the channel portion includes a first region overlapping the trench and a second region not overlapping the trench, and
wherein when a longitudinal direction of the channel portion is a first direction, the first region and the second region extend from the first connecting portion to the second connecting portion based on the first direction.

2. The thin film transistor of claim 1, wherein an effective gate voltage applied to the first region is different from an effective gate voltage applied to the second region.

3. The thin film transistor of claim 1, wherein a distance between an upper surface of the base substrate and an upper surface of the active layer overlapping the trench is shorter than a distance between an upper surface of the base substrate and an upper surface of the active layer not overlapping the trench.

4. The thin film transistor of claim 1, further including:
a second light shielding layer disposed on the first light shielding layer and overlapping the active layer, and
a second buffer layer disposed between the first light shielding layer and the second light shielding layer.

5. The thin film transistor of claim 4, wherein the second light shielding layer includes a hole overlapping the trench in a plane view, and
wherein an entire area of the hole overlaps the trench in a plane view.

6. The thin film transistor of claim 1, wherein the trench includes at least one of a first trench overlapping the first connecting portion; and a second trench overlapping the second connecting portion; and
the first trench and the second trench are spaced apart from each other.

7. The thin film transistor of claim 6, wherein the first trench includes a first sub-trench and a second sub-trench that are spaced apart from each other, and
the second trench includes a first sub-trench and a second sub-trench that are spaced apart from each other.

8. The thin film transistor of claim 1, wherein the trench includes a third trench that does not overlap the first connecting portion and the second connecting portion.

9. The thin film transistor of claim 8, wherein the third trench includes a first sub-trench and a second sub-trench that are spaced apart from each other.

10. The thin film transistor of claim 6, wherein the trench includes the first trench and the second trench, and
wherein any straight line parallel to the first direction and passing through the first trench pass through the second trench.

11. The thin film transistor of claim 6, wherein the trench includes the first trench and the second trench, and
wherein any straight line parallel to the first direction and passing through the first trench does not pass through the second trench.

12. A thin film transistor comprising:
a base substrate;
a first light shielding layer on the base substrate;
a first buffer layer on the first light shielding layer;
an active layer on the first buffer layer; and
a gate electrode spaced apart from the active layer and overlapping at least a portion of the active layer;
wherein the active layer includes:
a channel portion overlapping the gate electrode;
a first connecting portion connected to one side of the channel portion; and
a second connecting portion connected to the other side of the channel portion;
wherein the first light shielding layer overlaps the active layer,
wherein the first buffer layer includes a protrusion that overlaps at least a portion of the gate electrode in a plane view,
wherein the channel portion includes a third region overlapping the protrusion and a fourth region not overlapping the protrusion, and
wherein when a longitudinal direction of the channel portion is a first direction, the third region and the fourth region extend from the first connecting portion to the second connecting portion based on the first direction.

13. The thin film transistor of claim 12, wherein an effective gate voltage applied to the third region is different from an effective gate voltage applied to the fourth region.

14. The thin film transistor of claim 12, wherein a distance between an upper surface of the base substrate and an upper surface of the active layer overlapping the protrusion is longer than a distance between an upper surface of the base substrate and an upper surface of the active layer not overlapping the protrusion.

15. The thin film transistor of claim 12, further comprising:
a third light shielding layer disposed on the first light shielding layer and overlapping the protrusion, and
a second buffer layer disposed between the first light shielding layer and the third light shielding layer, and
wherein an entire area of the third light shielding layer overlap the protrusion in a plane view.

16. The thin film transistor of claim 12, wherein the protrusion includes at least one of a first protrusion overlapping the first connecting portion; and a second protrusion overlapping the second connecting portion; and
wherein the first protrusion and the second protrusion are spaced apart from each other.

17. The thin film transistor of claim 16, wherein the first protrusion includes a first sub-protrusion and a second sub-protrusion that are spaced apart from each other, and
wherein the second protrusion includes a first sub-protrusion and a second sub-protrusion that are spaced apart from each other.

18. The thin film transistor of claim 12, wherein the protrusion includes a third protrusion that does not overlap the first connecting portion and the second connecting portion.

19. The thin film transistor of claim 18, wherein the third protrusion includes a first sub-protrusion and a second sub-protrusion that are spaced apart from each other.

20. The thin film transistor of claim 16, wherein the protrusion includes the first protrusion and the second protrusion, and
wherein any straight line parallel to the first direction, passing through the first protrusion does not pass through the second protrusion.
